(19) United States
(12) Patent Application Publication
(10) Pub. No.: US 2026/0362656 A1
(43) Pub. Date: Nov. 12, 2026

(54) IMMERSION COOLING SYSTEMS AND RELATED METHODS

(71) Applicants: Casey Jamesen Carte, Portland, OR (US); Drew Damm, Beaverton, OR (US); Bruce Edward Pederson, Gales Creek, OR (US); Brendan T. Pavelek, Beaverton, OR (US); Eric D. Mcafee, Portland, OR (US)

(72) Inventors: Casey Jamesen Carte, Portland, OR (US); Drew Damm, Beaverton, OR (US); Bruce Edward Pederson, Gales Creek, OR (US); Brendan T. Pavelek, Beaverton, OR (US); Eric D. Mcafee, Portland, OR (US)

(21) Appl. No.: 19/722,761

(22) Filed: Jun. 27, 2026

(51) Int. Cl. H05K 7/20

(52) U.S. Cl. CPC H05K 7/20836; H05K 7/20236; H05K 7/20272; H05K 7/20781

(57) ABSTRACT

Immersion cooling systems and related methods are disclosed. An example apparatus includes an immersion tank having a first inlet and a second inlet different than the first inlet, a first coolant distribution unit (CDU) fluidly coupled to the first inlet of the immersion tank, a second coolant distribution unit (CDU) fluidly coupled to the second inlet of the immersion tank, and a controller. The controller to cause the first CDU to provide immersion fluid to the first inlet of the immersion tank at a first temperature that is within a first temperature threshold of a global temperature setpoint provided to the controller, and cause the second CDU to provide immersion fluid to the second inlet of the immersion tank at a second temperature that is within a second temperature threshold of a target manifold setpoint provided to the controller. The apparatus including an equipment rack. The immersion tank, the first CDU, the second CDU and the controller are coupled to the equipment rack.

### BACKGROUND

Rising thermal design power (TDP) in data-center servers has outpaced the capabilities of air-cooling methods. The use of liquids to cool electronic components provides benefits over more traditional air-cooling systems to address thermal management risks resulting from increased thermal design power in high performance systems.

### BRIEF DESCRIPTION OF THE DRAWINGS

FIG. 1A is an illustration of an example cooling system constructed in accordance with teachings disclosed herein.

FIG. 1B is front view of the example cooling system of FIG. 1A.

FIG. 1C is a perspective, rear view of the example cooling system of FIG. 1A.

FIG. 2A is a perspective front view of an example immersion tank of the example cooling system of FIGS. 1A-1C.

FIG. 2B is cross-sectional front view of the example immersion tank of FIG. 2A.

FIG. 2C is a perspective rear view of the example immersion tank of FIG. 2A shown without an example enclosure.

FIG. 3A is a perspective front view of an example cooling distribution unit of the example cooling system of FIGS. 1A-1C.

FIG. 3B is a perspective rear view of the example cooling distribution unit of the example cooling system of FIGS. 1A-1C.

FIG. 4 is a schematic illustration of the example cooling distribution unit and the example immersion tank of the example cooling system of FIGS. 1A-1C.

FIG. 5 is a schematic illustration of the example cooling distribution unit and an example target manifold of the example cooling system of FIGS. 1A-1C.

FIG. 6 is a block diagram of an example implementation of an example controller of the example cooling system of FIGS. 1A-1C.

FIG. 7 is a flowchart representative of example machine readable instructions and/or example operations that may be executed, instantiated, and/or performed by example programmable circuitry to implement the controller of FIG. 6.

FIG. 8 is a block diagram of an example processing platform including programmable circuitry structured to execute, instantiate, and/or perform the example machine readable instructions and/or perform the example operations of FIG. 7 to implement the controller of FIG. 6.

In general, the same reference numbers will be used throughout the drawing(s) and accompanying written description to refer to the same or like parts. The figures are not necessarily to scale.

### DETAILED DESCRIPTION

Rising thermal design power (TDP) of accelerated/cross-platform processing units (XPU) in data centers can surpass the capacity of air-cooling methods. Single-phase immersion cooling, which uses a tank of dielectric fluid to absorb heat from hardware, offers an alternative to air-cooling systems. Examples of dielectric liquids (e.g., electrically insulative liquids) include, but are not limited to, hydrocarbons (e.g., mineral oil, hexane, castor oil, etc.), deionized water, silicone oil, artificial coolants (e.g., fluorinated ketones, per-fluorinated compounds, etc.), benzene, liquid noble gases, liquid oxygen, and/or liquid hydrogen. Single-phase immersion systems include tanks that are self-contained (i.e., immersion fluid does not enter or leave the tank without external fluid delivery systems). Therefore, external systems are coupled to the tank to transfer absorbed heat to the environment. A common approach uses process chilled water (PCW) supplied by a data-center source and circulated through a coolant distribution unit (CDU) that is thermally coupled to the tank. The CDU controls PCW upstream of the tank and achieves precise bulk immersion fluid temperature.

Although such systems provide repeatable bulk immersion temperature, most single-phase immersion tanks rely on natural convection and lack discrete temperature or flow control. As a result, these systems do not offer the ability to independently heat or cool immersion fluid for specific server regions, limiting the ability to maintain optimal operating temperatures. Consequently, temperature distribution within the tank varies, creating hot spots near high-TDP components, and so variable heat loads are not accommodated. For instance, the temperature distribution inside the tank (e.g., along server blades) is variable, and hot spots of immersion fluid could develop near high-TDP regions. In other words, most single-phase immersion tanks rely on natural convection and lack precise temperature and flow control at discrete points or locations within the tank that can result in localized hot spots near high-TDP components. This shortcoming makes it challenging to cool or maintain precise thermal conditions for cooling high-TDP components (e.g., XPUs), which is needed to maintain optimal performance.

Moreover, system components (e.g., tanks) lack integrated mechanisms for equipment service, often requiring large overhead cranes to extract hardware or server components from the immersion liquid, which are costly and impractical for edge deployments. Moreover, single-phase immersion tanks cannot accommodate different server form factors without redesigning an enclosure, thereby limiting scalability across enterprise, cloud, and edge markets.

The disclosed embodiments provide example cooling systems that deliver independent temperature and/or flow control to immersion tanks and to targeted hardware regions or processing units within the tank including, but not limited to, accelerated/cross-platform processing units (XPUs), graphic processing units (GPUs), central processing units (CPUs), tensor processing units (TPUs), neural network processing units (NPUs), data processing units (DPUs), infrastructure processing units (IPUs), function accelerator cards (FACs), network attached processing unit (NAPU), and/or other processing units that offload and accelerate specialized tasks more efficiently.

To enable precise, independent temperature and flow control, example immersion cooling systems disclosed herein employ two or more independent, rack-mounted coolant distribution units (CDUs) that regulate both temperature and/or flowrates of immersion fluid. In this manner, examples disclosed herein replace passive convection cooling with active, programmable control. Each CDU maintains a primary PCW loop, a secondary immersion loop and a central plate heat exchanger to transfer energy between the primary PCW loop and the secondary immersion loop. Example pumps (e.g., variable-frequency-drive (VFD) pumps) circulate the immersion fluid based on programmable setpoints. Each CDU can independently heat or cool its supply. Thus, a first CDU can be employed to deliver hotter or cooler immersion fluid through a targeted manifold for high-TDP regions (e.g., XPUs), while a second CDU can be employed to deliver immersion fluid to an immersion tank having a global or overall tank temperature. As a result, hot spots near high-TDP components can be eliminated or reduced.

Some example systems and methods disclosed herein employ a controller (e.g., a programmable logic controller (PLC)) that hosts telemetry from the CDUs and the immersion tank, and provides real-time data display (e.g., via a touchscreen interface). The controller allows inputs to adjust heating or cooling PID modes, change flow setpoints, and activate or deactivate individual CDUs. The immersion tank includes a first or top-side targeted flow manifold and a second or bottom-side global flow manifold. A dedicated weir vessel collects overflow fluid from the tank's top and returns it to the CDUs for recirculation, ensuring stable operating conditions over long periods. Integrated into a frame of the immersion tank is a hoist assembly and drying vessel. The hoist assembly enables servers or components within the immersion tank to be to be lifted or removed from the immersion tank and moved directly over the drying vessel without external cranes. The drying vessel captures residual immersion fluid from the servers in a catch basin. Moreover, the example systems disclosed herein employ modular brackets that enable interchangeability of electronic components (e.g., AI blade, 21 inch AI blades) to enable use of the cooling system for different server form factors, enabling the cooling systems to be scalable across different environments (e.g., enterprise, cloud and edge environments). Thus, examples disclosed herein provide precise, independently controlled immersion fluid to specific components (e.g., XPUs), simplify server extraction through an integrated hoist/drying vessel, and offer a modular platform adaptable to diverse customer needs.

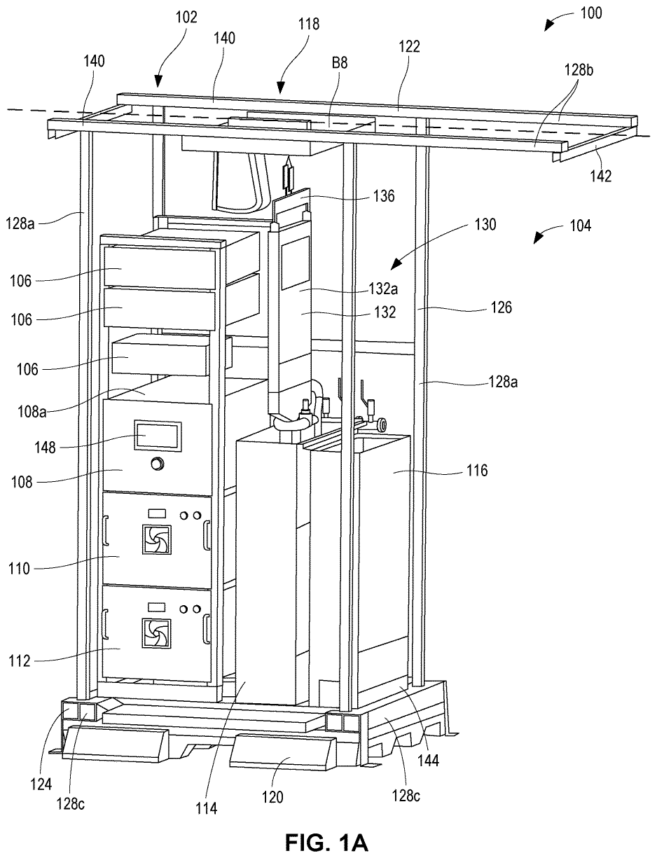

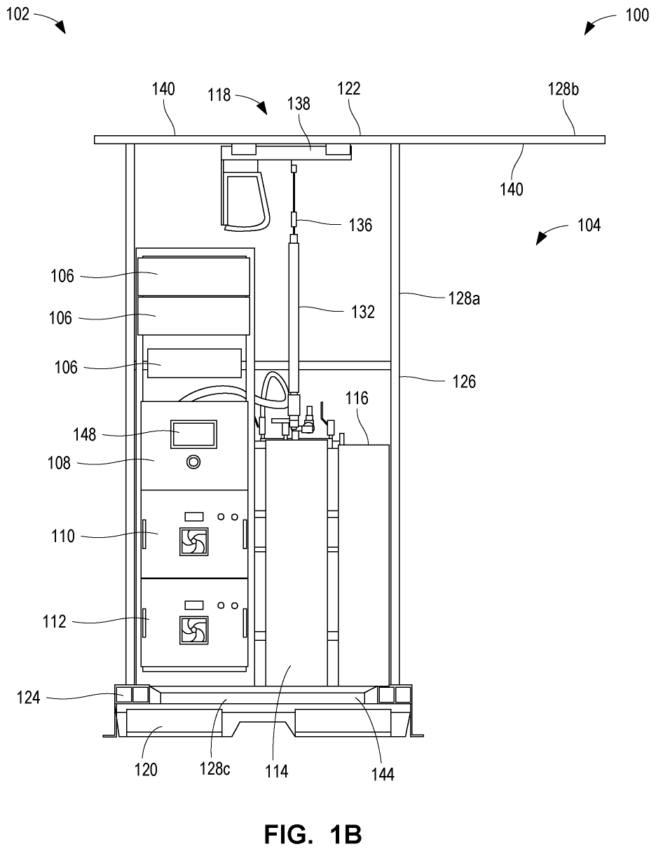

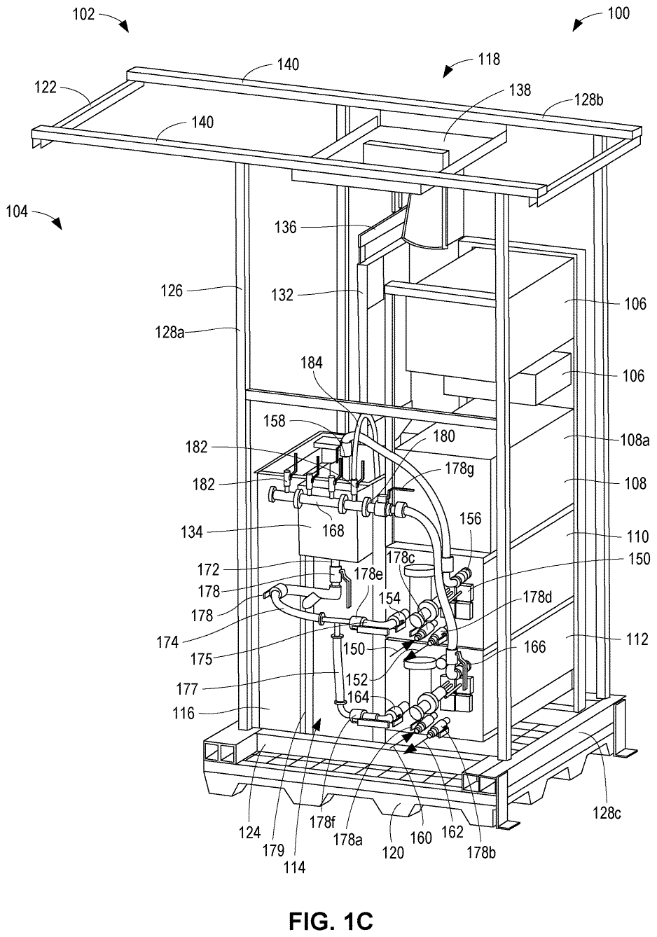

FIG. 1A is a perspective front view of an example cooling system 100 in accordance with teachings of this disclosure. FIG. 1B is a front view of the example cooling system 100 of FIG. 1A. FIG. 1C is a perspective rear view of the example cooling system 100 of FIG. 1A. Referring to FIGS. 1A-1C, the cooling system of 100 is a modular single-rack, single-phase immersion fluid cooling system assembly 102. In this example, the cooling system 100 can be implemented at a datacenter.

The cooling system 100 includes an equipment rack 104 (e.g., a frame assembly or rack enclosure) to support one or more infrastructure components 106, a controller 108 (e.g., control circuitry), a first coolant distribution unit (CDU) 110, a second coolant distribution unit (CDU) 112, an immersion tank 114, a drying vessel 116 and a hoist system 118 (e.g., a hoist assembly). As shown in FIGS. 1A-1C, the cooling system 100 includes a spill container 120 (e.g., a removable drip pan, a tray, etc.). In some examples, the drying vessel 116 can be omitted. In some examples, the spill container 120 is not included.

The cooling system 100 of the illustrated example is a rack-mounted, stand-alone assembly (e.g., an all-in one unit) in which all or substantially all components are housed within or coupled to the single equipment rack 104. For example, the CDUs 110, 112, the controller 108, telemetry and power supplies, the hoist system 118, the immersion tank 114, the drying vessel 116, and the spill container 120 (e.g., optional) are housed within or coupled to the single equipment rack 104. This compact modular design allows an entire cooling system to be installed directly on standard data-center racks without additional external framing and/or crane-mounted supports. The entire assembly is mounted on the rack-mounted frame 102, with all or substantially all elements designed for modular interchangeability (e.g., interchangeable brackets for different server form factors) and integrated hoist/drying vessel access to facilitate servicing. Telemetry can be provided as part of the equipment rack 104 to allow the cooling system 100 to be implemented in environments with limited space (e.g., an edge environment).

The equipment rack 104 includes a hoist support frame 122, a base support frame 124 opposite the hoist support frame 122, and a side support frame 126 extending between the base support frame 124 and the hoist support frame 122. The side support frame 126 includes a plurality of first beams 128a having respective first and second ends that extend between and/or are fixed to the base support frame 124 and the hoist support frame 122. The hoist support frame 122 includes a plurality of second beams 128b (e.g., parallel or horizontal beams) coupled to the upper ends of the side support frame 126. The base support frame 124 includes a plurality of third beams 128c (e.g., a rectangular-shaped beams). The equipment rack 102 defines an opening or area 130 to receive the infrastructure components 106, the controller 108, the first CDU 110, the second CDU 112, the immersion tank 114 and the drying vessel 116.

The infrastructure components 106 of the illustrated example can include, but are not limited to, a terraform module or infrastructure as code (IoC) module, data store, schema components, compute components, networking components, power supplies and/or any other components for implementing a server or data center. The infrastructure components 106 are coupled or mounted to the equipment rack 104. For example, the infrastructure components 160, the controller 108 (e.g., a PLC chassis), the CDUs 110, 112, telemetry, etc., couple to a sub-rack (e.g., a 19 inch rack).

The immersion tank 114 of the illustrated example holds an immersion fluid (e.g., a source fluid, oil, dielectric liquid, etc.) into which one or more electronic components 132 (e.g., servers) is immersed or submerged. In this example, the electronic component 132 is a server blade 132a. The immersion tank 114 includes interchangeable or modular brackets to support different blade form factors (e.g., a 21 inch AI blade form factor), enabling the same core platform to serve enterprise, cloud and edge markets. The immersion tank 114 can receive one or more server blades 132a. The immersion tank 114 is filled with an immersion fluid that absorbs heat directly from the electronic component 132 and, in some examples, eliminating the need for fans. The immersion tank 114 is manages (e.g., primarily manages) heat from high-density computing workloads or high-TPD components. The immersion tank 114 supports a weir vessel 134 (e.g., a weir tank) (FIGS. 1B and 1C). Specifically, immersion fluid from the immersion tank 114 discharges into the weir vessel 134. The immersion fluid in the weir vessel 134 recirculates to the first CDU 110 and/or the second CDU 112.

To insert or remove the electronic component 132 from the immersion tank 114, the cooling system 100 of the illustrated example includes the hoist system 118. As shown in FIGS. 1A-1C, the electronic component 132 is suspended above the immersion tank 114 by the hoist system 118. The hoist system 118 of the illustrated example is coupled to the hoist support frame 122. The hoist system 118 includes a hoist 136 (e.g., a winch) that is mounted to or carried by a carriage or trolley 138. The trolley 138 moves or slides along rails 140 provided by the second beams 128b of the hoist support frame 122. In other words, the trolley 138 slides or moves along the hoist support frame 122 along a longitudinal axis 142 (e.g., a horizontal axis in the orientation of FIGS. 1A-1C) of the hoist support frame 122. In this example, the trolley 138 includes wheels or rollers that interact with a track or channel provided by the rails 140 (e.g., the second beams 128b). In this example, the hoist 136 is manually operated (e.g., a user imparts a force to the trolley 138 to move it sideways along the rails 140). However, in some examples, the hoist 136 and/or trolley 138 can be operated by a motor. For example, a first switch can be included on the equipment rack 104, the hoist system 118 or the controller 108 to operate or cause movement (e.g., vertical movement) of the hoist 136 relative to the immersion tank 114 and/or a second switch can be included on the equipment rack 104, the hoist system 118 or the controller 108 to operate or cause movement (e.g., horizontal movement) of the trolley 138 along the rails 140. Thus, the cooling system 100 of the illustrated example includes a built-in hoist system (e.g., a built-in hoist and trolley assembly).

The cooling system 100 of the illustrated example incorporates the drying vessel 116 (e.g., an integrated drying vessel) positioned adjacent to the immersion tank 114. The drying vessel 116 includes a catch basin or container to collect residual immersion fluid when the electronic component 132 is lifted from the immersion tank 114 and positioned within or suspended above the drying vessel 116 via the hoist system 118. For example, the hoist 136 can be employed to remove the electronic component 132 from the immersion tank 114 and the trolley 138 can be employed to move the electronic component 132 to a position that is inside or suspended above the drying vessel 116 to drain residual immersion fluid from the electronic component 132 in the drying vessel 116. In this example, a bottom of the drying vessel 116 has a chamfered angle to funnel the immersion fluid to a container or tray 144 (e.g., a removable tray) for recapture. For example, the tray 144 can be removed and the immersion fluid within the tray 144 can be poured into the immersion tank 114. In some examples, the drying vessel 116 can include a return system (e.g., a pump, valve and/or other fluid system to) recirculate residual immersion fluid from the drying vessel 116 directly to the immersion tank 114 (e.g., without manual intervention or use of the tray 144). By draining liquid directly into the drying vessel 116, the cooling system 100 eliminates the need for large overhead cranes or external spill containment, which can be beneficial for edge deployments where space is limited.

The first CDU 110 and the second CDU 112 are coupled to or supported by the equipment rack 104. The first CDU 110 can operate independently of the second CDU 112. For example, the first CDU 110 maintains or adjusts a global temperature the immersion fluid of the immersion tank 114 via cooling or heating. The second CDU 112 provides temperature control to targeted regions (e.g., high-TDP XPUs) within the immersion tank 114 (e.g., adjacent an upper end of the immersion tank 114). As described in greater detail below, the first CDU 110 and the second CDU 112 precisely regulate a global immersion fluid temperature and targeted immersion fluid temperature and/or flowrates via heating, cooling and flowrate adjustments. The first CDU 110 and the second CDU 112 of the illustrated example are structured identically. However, in some examples, the first CDU 110 and the second CDU 112 can be different (e.g., different in size, different in volume, manufactured by different manufacturers, hold different number of electronic components, contain different types of the immersion fluid, etc.).

The controller 108 of the illustrated example is a programmable logic controller (PLC) having a chassis 108a mounted to the equipment rack 104. The controller 108 of the illustrated example controls operation of the first CDU 110 and the second CDU 112 independently. For example, the controller 108 controls the first temperature output of the immersion fluid of the first CDU 110 independently from the second temperature output of the immersion fluid of the second CDU 112. Likewise, the controller 108 controls the first flowrate output of the first CDU 110 independently from the second flowrate output of the second CDU 112. Moreover, the controller 108 of the cooling system 100 controls a first temperature output of the immersion fluid of the first CDU 110 independently from a first flowrate output of the immersion fluid of the first CDU 110. Additionally, the controller 108 of the cooling system 100 controls a second temperature output of the immersion fluid of the second CDU 112 independently from a second flowrate output of the immersion fluid of the second CDU 112. In this manner, the first temperature can be different or the same as the second temperature, and/or the first flowrate can be the same or different from the second flowrate. For example, each of the first CDU 110 and the second CDU 112 can heat or cool its supply fluid and/or regulate flowrate, enabling hotter or cooler immersion fluid to be delivered selectively through targeted regions (e.g., for high-TDP XPUs), while maintaining a global or overall immersion tank temperature. The controller 108 of the illustrated example hosts telemetry from the first CDU 110, the second CDU 112, and the immersion tank 114, providing real-time or substantially real-time data via a display 148 (e.g., via a touchscreen interface). For example, the display 148 can present global tank conditions (e.g., overall temperature and flow), targeted flow manifold conditions (e.g., temperature and flow near high-TDP components) and/or status indicators for each CDU 110, 112 (e.g., operational state, fault condition, etc.).

In some examples, the display 148 can include a touchscreen that presents an emergency shut-off switch (EMO). In some examples, an EMO can be a physical switch integrated in the controller 108. The controller 108 allows inputs to adjust heating or cooling (e.g., PID) modes, adjust temperature set points, adjust flowrate setpoints, and activate or deactivate the CDUs 110, 112 (e.g., via an input or touch screen interface). In some examples, the controller 108 calculates control signals using a PID algorithm to maintain each CDU's target immersion fluid temperature within ±X °C (e.g., ±5 degrees Celsius) of its setpoint, determines variable-frequency-drive pump speeds for both the PCW and immersion fluid loops to achieve specified flowrate targets, generates on/off or duty-cycle commands to each CDU's heater, cooler, valve array, and pump and/or logs all telemetry and actuation events for auditability.

Referring to FIG. 1C, the first CDU 110 includes a first PCW inlet 150 (PCWᵢₙ₁) to receive PCW from a PCW supply source (not shown) and a first PCW outlet 152 (PCWₒᵤₜ₁) to return the PCW to the PCW supply source. Additionally, the first CDU 110 includes a first immersion fluid (IF) inlet 154 (Fluidᵢₙ₁) fluidly coupled to a first tank inlet 158 (tankᵢₙ₁) to provide or distribute immersion fluid to the immersion tank 114. As described in greater detail herein, the first IF inlet 154 provides immersion fluid to the immersion tank 114 to maintain or adjust a global immersion fluid temperature within the immersion tank 114.

The second CDU 112 includes a second PCW inlet 160 (PCWᵢₙ₂) fluidly coupled to receive the PCW from the PCW supply source and a second PCW outlet 162 (PCWₒᵤₜ₂) to return the PCW to the PCW supply source. Additionally, the second CDU 112 includes a second IF inlet 164 (Fluidᵢₙ₂) fluidly coupled to a second tank inlet 180 (tankᵢₙ₂) to provide or distribute immersion fluid to the specific or targeted areas of the immersion tank 114.

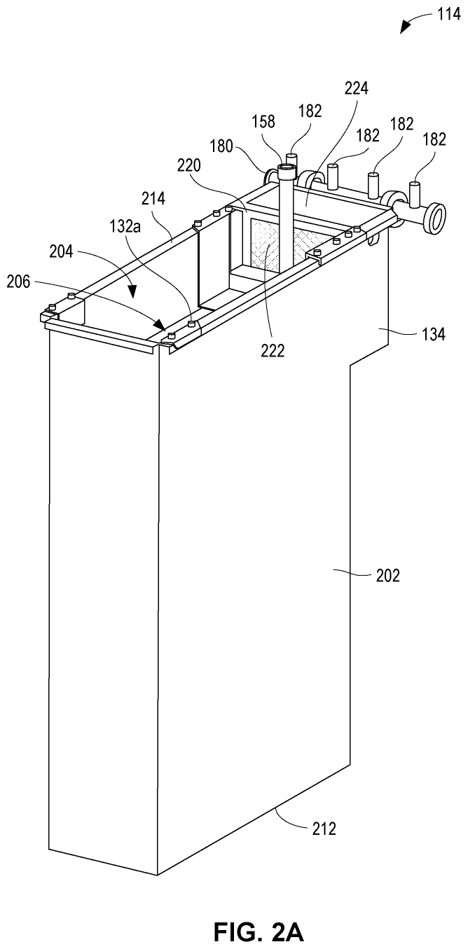

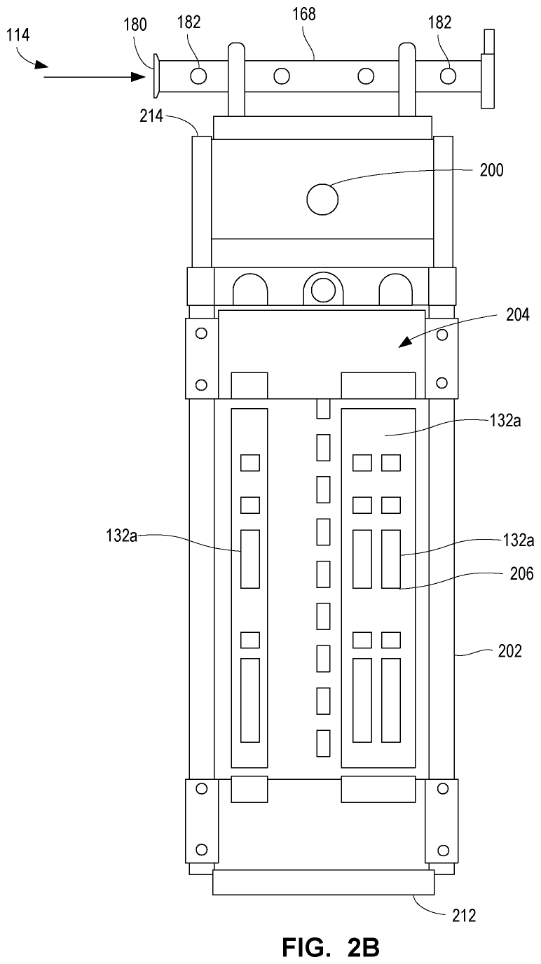

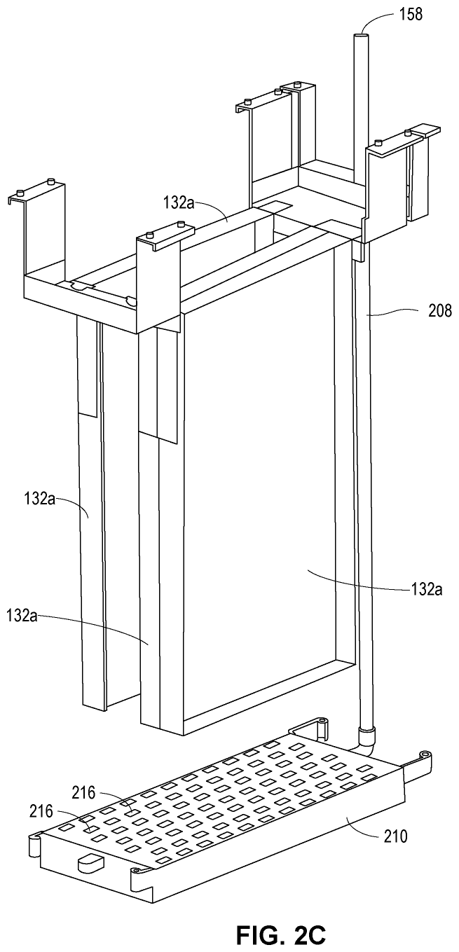

As described in detail below, the second tank inlet 180 of the illustrated example is a target manifold 168 that can distribute immersion fluid to targeted regions within the immersion tank 114 at a target temperature (e.g., different than the global temperature). The target manifold 168 a manifold inlet (e.g., the second tank inlet 180) to receive immersion fluid from the second CDU 112 (e.g., from the second IF outlet 166). The target manifold 168 of the illustrated example includes a plurality of outlets 182 (e.g., ports) distributed along a length of the target manifold 168. The manifold outlets 182 fluidly couple to target regions of the immersion tank 114 and/or to thermal management components of components coupled to the electronic component 132 (e.g., see FIGS. 2A-2C) via dedicated manifold fluid lines 184. For instance, the manifold fluid lines 184 can couple to ports or channels in the enclosure 202 (FIG. 2A) that each selectively direct or substantially direct (e.g., via jets, outlets, etc.) the immersion fluid onto a specific component of the electronic component 132 associated or aligned with the respective ones of the ports. In some examples, a manifold fluid line 184 can couple to an inlet of a cold plate of a component coupled to the electronic component 132. For clarity, only one manifold fluid line 184 is shown in FIG. 1C. However, in some examples, each of the manifold outlets 182 can include a dedicated manifold fluid line 184.

The immersion tank 114 of the illustrated example includes a tank outlet 200 (tankₒᵤₜ) (see FIGS. 2A-2C) that is fluidly coupled to the first IF inlet 154 (Fluidᵢₙ₁) and the second IF inlet 164 (Fluidᵢₙ₂). In this example, the tank outlet 200 (tankₒᵤₜ) discharges the immersion fluid from the immersion tank 114 to the weir vessel 134 (e.g., an overflow bucket) when a liquid level reaches the tank outlet 200. The weir vessel 134 has a weir outlet 172 that is fluidly coupled to the first IF inlet 154 of the first CDU 110 (e.g., via a first hose or fluid line 175) and the second IF inlet 164 of the second CDU 112 (e.g., via a second hose or fluid line 177) via a weir or return line 174 (e.g., an overflow line). The cooling system 100 recirculates immersion fluid in a closed loop that starts from the tank outlet 200 and flows to the first and second CDUs 110, 112 for recirculation. The weir vessel 134 has an overflow tube 179 that discharges into the spill container 120.

In the illustrated example, immersion fluid from the tray 144 of the drying vessel 116 can be poured into the immersion tank 114. However, in some examples, the immersion fluid that drains from of the drying vessel 116 can be routed back into a recirculating loop 174 of the cooling system 100. For example, residual immersion fluid from the drying vessel 116 can enter the return line 174 that recirculates or feeds into the first CDU 110 and the second CDU 112. In some examples, a return line can carry this residual fluid from the drying vessel 116 into the immersion tank 114, which is then routed to the first CDU 110 and/or the second CDU 112 for recirculation. For example, residual immersion fluid from the drying vessel 116 can flow to the tray 144, which can then be emptied or returned into the immersion tank 114 via a recirculation pump and fluid line.

Additionally, each of the first CDU 110 and the second CDU 112 may be independently enabled or disabled by the controller 108, allowing either unit to be selectively deactivated (e.g., turned off) while the other continues operation. Additionally or alternatively, the first CDU 110 and the second CDU 112 can be disabled or turned off by one or more valves 178. For example, the first PCW inlet 150 can include a first valve 178a (e.g. a ball valve), the second PCW inlet 160 can include a second valve 178b (e.g., a ball valve), the first IF inlet 154 can include a third valve 178c (e.g. a ball valve), and the second IF inlet 164 can include a fourth valve 178d (e.g., a ball valve). Additionally or alternatively, the first fluid line 175 can include a fifth valve 178e (e.g., a ball valve) and the second fluid line 177 can include a sixth valve 178f (e.g., a ball valve). For example, the sixth valve 178f can be moved to an off position to restrict or prevent immersion fluid recirculation flow to the second CDU 112, if desired. Any of the valves 178 can be operated to adjust or affect flow or operation of the components.

FIG. 2A is a perspective front view of the immersion tank 114 of FIGS. 1A-1C. FIG. 2B is a cross-sectional front view of FIG. 2A. FIG. 2C is a perspective front view of the example immersion tank 114 of FIG. 2A shown without an enclosure 202 (e.g., a vessel, container, or outer panels). The enclosure 202 of the immersion tank 114 defines a cavity 204 to hold or contain an immersion fluid, into which the electronic component 132 (e.g., a server) is to be immersed or submerged. The cavity 204 of the illustrated example is sized to fit a rack unit of approximately 8.75 inches (222.25 millimeters)(e.g., roughly a 5-RU height); however, the cavity 204 can be sized to accommodate other rack sizes. The enclosure 202 of the illustrated example is welded at its seams to prevent leaks. The enclosure 202 of the illustrated example can be composed of stainless steel (e.g., 304 stainless steel for chemical compatibility) and/or any other suitable material(s) (e.g., steel, alloy, etc.).

The immersion tank 114 receives immersion fluid from the first CDU 110 via the first tank inlet 158. For example, the first tank inlet 158 of the illustrated example includes an inlet pipe 208 (e.g., a one-inch diameter copper tube) and a global distribution grate 210 (FIG. 2C) (e.g. a global distribution manifold). The global distribution grate 210 is provided on or adjacent a bottom or lower end 212 of the enclosure 202. The inlet pipe 208 channels the immersion fluid from the first CDU 110 from an upper end 214 of the enclosure 202 and terminates at the global distribution grate 210 positioned adjacent the lower end 212 of the enclosure 202. The global distribution grate 210 includes a plurality of openings 216 that allows the immersion fluid to flow into the cavity 204 of the immersion tank 114 and allows any residual air to escape. The global distribution grate 210 provides bulk circulation for overall or global temperature maintenance of the immersion fluid within the enclosure 202. The immersion fluid from the global distribution grate 210 flows from the lower end 212 of the enclosure 202 or cavity 204, which causes the immersion fluid in the immersion tank 114 to rise upward toward the upper end 214 of the tank outlet 200 and ultimately flows into the weir vessel 134.

The target manifold 168 of the illustrated example is coupled to the upper end 214 of the immersion tank 114. The target manifold 168 of the illustrated example is directly mounted to the enclosure 202. The target manifold 168 (e.g., the targeted-flow manifold) delivers immersion fluid from the second CDU 112 directly to selected high-TDP components (e.g., XPUs). The target manifold 168 of the illustrated example includes a manifold inlet 280 (e.g., the second tank inlet 180) fluidly coupled to the second IF outlet 166 of the second CDU 112 and the manifold outlets 182 that are fluidly coupled to respective ones TPD regions (e.g., heat sinks, XPUs, and/or PCB regions) associated with the electronic component 132. In this example, each of the manifold fluid lines 184 (FIG. 1C) can terminate with a fitting that mates with an inlet on a target hardware, allowing the heated/cooled immersion fluid from the second CDU 112 to be injected or distributed at defined locations within the enclosure 202. For example, the manifold outlets 182 can be fluidly coupled to inlets (e.g., inlet cold plates) associated with or coupled to target components via the manifold fluid lines 184 (e.g., hoses) such that the heated/cooled immersion fluid from the second CDU 112 pass through cold plates of the target components. For example, the manifold outlets 182 can be directly or indirectly fluidly coupled to respective ones of cold plates of different components (e.g., XPUs, GPUs, etc.) of the electronic components 132 (e.g., server blades). In some examples, the immersion fluid flows from a manifold outlet 182 through the cold plate and exits within the cavity 204 of the enclosure 202, mixing with the immersion fluid in the enclosure 202. In some examples, an outlet of the target cold plate can fluidly couple to the second CDU 112 (e.g., the second IF inlet 164) to recirculate the immersion fluid that exits from the cold plate directly to the second CDU 112. In some such examples, the second CDU 112 provides a closed loop immersion fluid system and the second CDU 112 can employ an immersion fluid that is different from the immersion fluid of the immersion tank 114.

In some examples, the manifold fluid lines 184 are not physically coupled to (e.g., cold plates of) the target components, but simply project or eject the immersion fluid (e.g., via nozzle or jet) directly onto or toward target components within the enclosure 202. In some examples, the immersion tank 114 itself includes multiple flow channels (e.g., channel structures) to direct the immersion fluid from the manifold outlets 182 to the TPD regions. Thus, the target manifold 168 is not only capable of being mechanically coupled to specific components, but it can also be integrated into a network of internal flow channels provided in the enclosure 202 or via fluid lines to targeted components.

The weir vessel 134 is mechanically coupled or attached to the immersion tank 114 near the upper end 214 of the enclosure 202 (e.g., near the tank outlet 200). The weir vessel 134 contains a weir plate 220 that sets or defines a maximum fluid level in the immersion tank 114. When the immersion fluid rises above (e.g., a lower end of) the weir plate 220, the immersion fluid flows through an attached weir screen/filter 222 and into the weir bucket or weir cavity 224. The weir outlet 172 (FIG. 1C) returns the immersion fluid back to the first CDU 110 and the second CDU 112 for recirculation (e.g., thereby maintaining a stable bulk temperature and preventing over-pressure buildup).

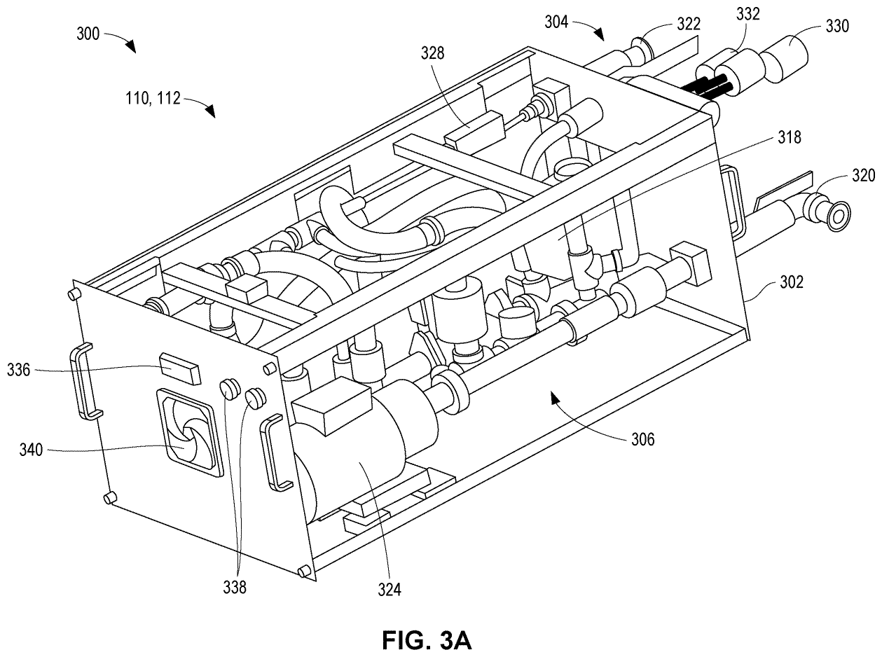

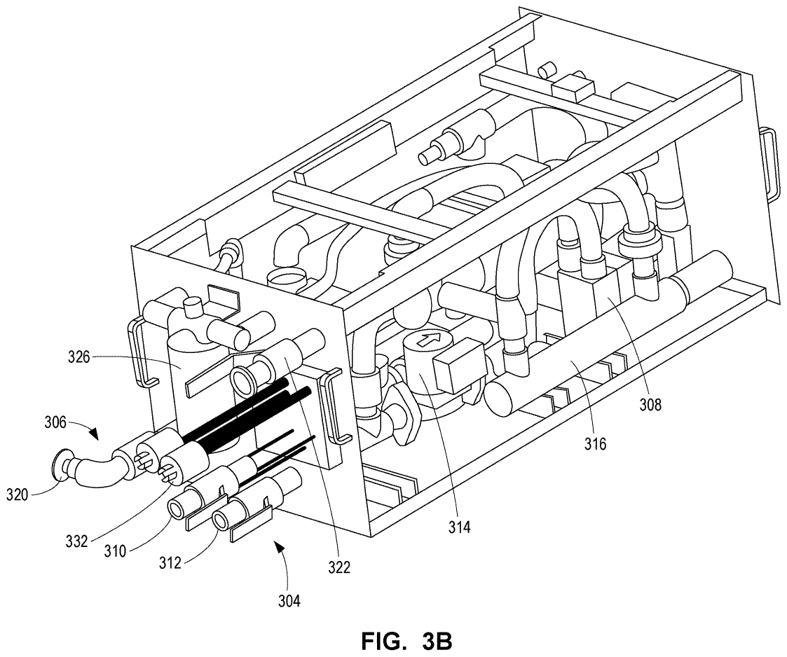

FIG. 3A is a perspective front view of a CDU 300 that can implement the first CDU 110 and the second CDU 112 of FIGS. 1A-1C. FIG. 3B is a perspective rear view of the CDU 300 of FIG. 3A.

The CDU 300 includes a housing 302 to encase components of the CDU 300. As shown in FIGS. 3A and 3B, portions of the housing 302 are removed to enhance clarity. The CDU 300 includes a first closed-loop path or PCW loop 304 for the PCW supply fluid (e.g., a water side), a second closed-loop path or IF loop 306 for the immersion fluid (e.g., an oil side), and a central heat exchanger 308 (FIG. 3B) that provides energy transfer between the PCW supply fluid in the PCW loop 304 and the immersion fluid in the IF loop 306, enabling precise thermal regulation. The PCW loop 304 includes a PCW inlet 310 (e.g., the PCW inlet 150, 162 of FIG. 1C), a PCW outlet 312 (i.e., the PCW outlet 152, 162 of FIG. 1C), a PCW pump 314 (e.g., a recirculation pump), a PCW heater 316 (e.g., 2 kilowatt (KW) heater), and a PCW control valve 318. The IF loop 306 includes an IF inlet 320 (e.g., the IF inlets 154, 164 of FIG. 1C), an IF outlet 322 (e.g., the IF outlets 156, 166 of FIG. 1C), an immersion fluid (IF) pump 324, an immersion fluid (IF) filter 326, and an immersion fluid (IF) flow sensor 328. The CDU 300 includes power cables 330 to provide power the CDU 300 (e.g., power components including pumps, sensors, heaters, etc.) and/or data cables 332 to establish data communication between the CDU 300 and the controller 108 and/or the infrastructure components. For example, the PCW pump 314, the PCW heater 316, the PCW control valve 318, the IF pump 324, and the IF flow sensor 328 are communicatively coupled to the controller 108 and/or provide feedback signals representative of operating characteristics of the PCW supply fluid, the immersion fluid, and/or the respective components (e.g., the PCW pump 314, the PCW heater 316, the PCW control valve 318, the IF pump 324 and/or the IF flow sensor 328). The IF pump 324 of the illustrated example is a variable-frequency-drive (VFD) pump and its speed is set by the controller 108 to achieve desired flowrates through the IF loop 306 and/or the IF outlet 322. The IF flow sensor 328 monitors immersion fluid flowrates through the IF outlet 322. In some examples, the first IF flow sensor 328 is a magnetic inductance flowmeter. In other examples, different types of flowmeters may be employed. The CDU 300 includes a monitor display panel 336 to display fluid characteristics of the immersion fluid in the IF loop 306 and/or fluid characteristics of the PCW fluid in the PCW loop 304, indicator lights 338 (e.g., safety or warning lights) and a fan 340 to dissipate heat from the housing 302 of the CDU 300.

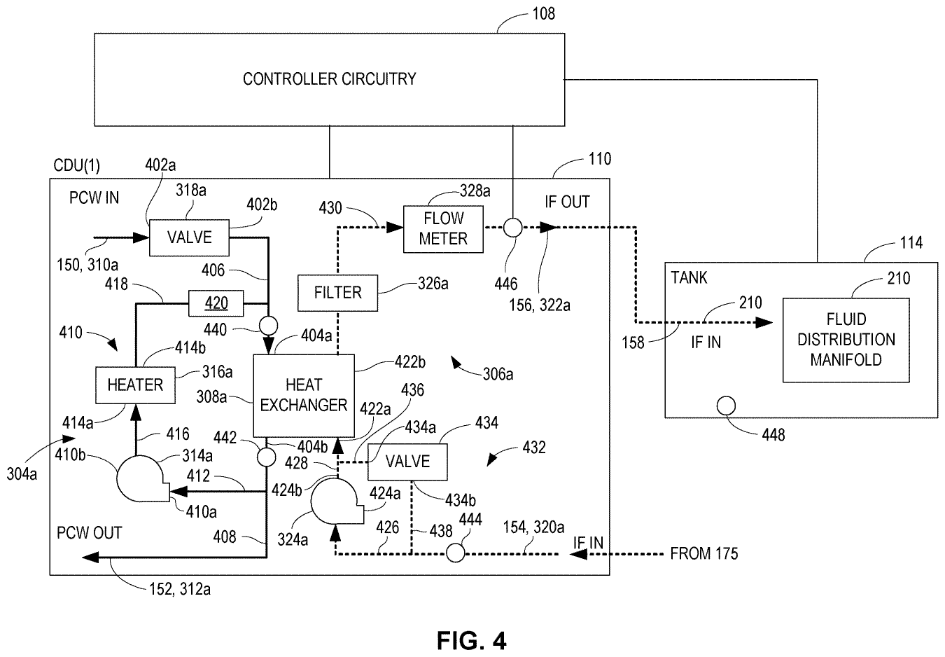

FIG. 4 is a schematic system of the first CDU 110 and the immersion tank 114. The first CDU 110 provides or supplies temperature-controlled immersion fluid to maintain the temperature of the immersion fluid in the immersion tank 114 based on a global temperature setpoint provided to the controller 108. Importantly, the first CDU 110 operates independently of the second CDU 112 so that each unit can regulate a temperature and/or flowrate of the immersion fluid independently of one another.

To control temperature of the immersion fluid based on the global temperature set point, the first CDU 110 features two closed loops: a first PCW loop 304a and a first IF loop 306a. A first heat exchanger 308a transfers energy between the PCW supply fluid in the first PCW loop 304a and the immersion fluid in the first IF loop 306a, enabling regulation of the immersion fluid temperature passing through the first heat exchanger 308a. In this example, the first CDU 110 regulates (e.g., primarily regulates) the temperature of the immersion fluid in the first IF loop 306a by exchanging heat with the PCW supply fluid in the first PCW loop 304a via the first heat exchanger 308a.

PCW supply fluid enters the first CDU 110 through the first PCW loop 304a. For instance, the first CDU 110 receives PCW supply fluid via the first PCW inlet 310a, 150 (e.g., an inlet valve 178) that couples a PCW fluid supply source. A first PCW control valve 318a of the first CDU 110 regulates or sets the flow of PCW supply fluid into the first PCW loop 304a. For example, the first PCW control valve 318a has a first control valve inlet 402a that is fluidly coupled to the first PCW inlet 150, 310a and a first control valve outlet 402b that is fluidly coupled to a PCW-side heat exchanger inlet 404a (e.g., via a first PCW fluid line 406) of the first heat exchanger 308a. The first heat exchanger 308a is fluidly coupled to the first PCW outlet 152, 312a of the first CDU 110. For example, the first PCW outlet 152, 312a is fluidly coupled to a PCW-side heat exchanger outlet 404b of the first heat exchanger 308 (e.g., via a second PCW fluid line 408).

To adjust (e.g., raise or lower) a temperature of the PCW supply fluid, the first PCW loop 304a includes a first heating system 410 (e.g., a heating subloop). The first heating system 410 circulates the PCW supply fluid through the first heater 316a and the PCW-side of the first heat exchanger 308a. The first heating system 410 (e.g., a first heating system) has a first PCW pump 314a and a first heater 316a. The first PCW pump 314a circulates the PCW supply fluid from the PCW-side heat exchanger outlet 404b through the first heater 316a before returning it to the PCW-side heat exchanger inlet 404a of the first heat exchanger 308a, allowing the controller 108 to raise the temperature of the PCW supply fluid (e.g., if required by a control logic). The first inlet valve 318a and the first PCW pump 314a are positioned on the PCW-side of the first heat exchanger 308a. For example, the first PCW pump 314a includes a first PCW pump inlet 410a in fluid communication with the PCW-side heat exchanger outlet 404b (e.g., via a third fluid line 412). A first PCW pump outlet 410b of the first PCW pump 314a is fluidly coupled to a first heater inlet 414a of the first heater 316a (e.g., via a fourth fluid line 416), and a first heater outlet 414b of the first heater 316a is fluidly coupled to the PCW-side heat exchanger inlet 404a (e.g., via a fifth fluid line 418). The fifth fluid line 418 includes a valve 420 (e.g., a one-way valve) to prevent PCW supply fluid from flowing from the first PCW control valve 318a to the first heater 316a without first passing through the first heat exchanger 308a.

The first IF loop 306a circulates immersion fluid from the immersion tank 114 through an IF-side of the first heat exchanger 308a and returns the immersion fluid to the immersion tank 114 via the first IF outlet 156, 322a based on the global temperature set point of the controller 108. A first IF pump 324a draws fluid from the first IF inlet 154, 320a and directs the immersion fluid to an IF-side heat exchanger inlet 422a of the first heat exchanger 308a. For example, the first IF pump 324a includes a first IF pump inlet 424a fluidly coupled to the first IF inlet 154, 320a of the first CDU 110 (e.g., via a first IF fluid line 426) and a first IF pump outlet 424b fluidly couples to the IF-side heat exchanger inlet 422a (e.g., via a second IF fluid line 428). A first IF-side heat exchanger outlet 422b of the first heat exchanger 308a is fluidly coupled to the first IF outlet 156, 322a (e.g., via a third IF fluid line 430).

Additionally, the first IF loop 306a includes a first bypass loop 432a to tune a temperature and/or a flowrate of the immersion fluid flowing through the first IF loop 306a. For example, the first bypass loop 432a allows immersion fluid to route from the IF pump outlet 424b to the IF pump inlet 424a to adjust a flowrate of the immersion fluid through the first heat exchanger 308a. For instance, the first bypass loop 432a includes a first bypass valve 434 having a first bypass valve inlet 434a in fluid communication with the IF pump outlet 424b (e.g., via a fourth IF fluid line 436) and a first bypass valve outlet 434b in fluid communication with the IF pump inlet 424a (e.g., via a fifth IF fluid line 438). By adjusting flow through the first bypass valve 434 (e.g., by opening/closing this valve), the first CDU 110 can adjust a flowrate of the immersion fluid entering the first heat exchanger 308a and, thus, exiting the first IF outlet 156, 322a. For example, by opening the first bypass valve 434, a portion of the immersion fluid flowing from the IF pump outlet 424b diverts to the first IF fluid line 426 and/or the IF pump inlet 424a via the first IF fluid line 426, allowing fine-tuning of both temperature and/or flowrate (e.g., velocity) provided to the first IF outlet 156, 322a and the immersion tank 114. By closing (e.g., fully closing) the first bypass valve 434, immersion fluid flowing from the IF pump outlet 424b flows (e.g., fully) to the IF-side heat exchanger inlet 422a without portions of the immersion fluid diverting through the first bypass loop 432, allowing greater or higher flowrate of the immersion fluid through the first heat exchanger 308a. After the first heat exchanger 308a, the immersion fluid passes through a first filter 326a (e.g., a 3-D printed or cartridge filter) that removes particulates from the immersion fluid and protects downstream components. A first IF flowrate sensor 328a is provided (e.g., installed) downstream of the first filter 326a. The first IF flow meter 328a measures (e.g., continuously or substantially continuously measures) immersion fluid throughput of the first IF loop 306a in real-time. The immersion fluid that exits the first IF outlet 156, 322a flows to the global distribution grate 210 of the immersion tank 114 before reentering the first IF loop 306a of the first CDU 110 for the next cycle.

During normal operation, the first CDU 110 adjusts or regulates a temperature of the immersion fluid based on (e.g., to match or substantially match) a global temperature setpoint for the immersion tank 114 provided to the controller 108. The energy exchange in the first IF loop 306a is driven by a flowrate and/or temperature of the PCW supply fluid circulating in the first PCW loop 304a. To implement the desired global temperature, the controller 108 controls (e.g., energizes or de-energizes) the first PCW pump 314a, the first heater 316a, the first IF pump 324a, and/or the first bypass valve 434 based on measured feedback or data provided to the controller 108.

To determine which components to control (e.g., activate or deactivate), the controller 108 receives data or feedback from one or more sensors. For example, the first CDU 110 includes a first PCW temperature sensor 440 (e.g., thermocouple) to measure PCW supply fluid temperature at the PCW-side heat exchanger inlet 404a, and a second PCW temperature sensor 442 (e.g., a thermocouple) to measure PCW supply fluid temperature at the PCW-side heat exchanger outlet 404b. In some examples, the first CDU 110 can include a first PCW flow meter to detect or measure a fluid flowrate of the PCW supply fluid at the first PCW inlet 150, 310a. In some examples, the first IF loop 306a includes a first IF temperature sensor 444 to measure immersion fluid temperature at the IF-side heat exchanger inlet 422a and a second IF temperature sensor 446 to measure immersion fluid temperature at the IF-side heat exchanger outlet 422b. The first IF flowrate sensor 328a provides a measured flowrate of the immersion fluid at the first IF outlet 156, 322a. Additionally, the immersion tank 114 includes a temperature sensor 448 (e.g., a thermocouple) to measure immersion fluid temperature in the immersion tank 114 (e.g., a measured global temperature).

The controller 108 monitors the immersion fluid temperature from the first IF temperature sensor 444 and/or the second IF temperature sensor 446 against a global temperature setpoint (e.g., a user-defined setpoint). If the immersion fluid temperature increases above the global temperature setpoint (e.g., 35 degrees Celsius), the first CDU 110 cools the immersion fluid by enabling cooler PCW supply fluid in the first PCW loop 304a to remove or absorb excess energy from the immersion fluid in the first IF loop 306a. In some examples, if the immersion temperature is within a threshold (e.g., plus or minus 2 degrees, 5 degrees, etc.) of the global temperature setpoint, the controller 108 can employ the first heating system 410 to keep the immersion fluid temperature at the first IF outlet 156, 322a steady, maintaining continuous cooling.

If the immersion fluid temperature falls below the global temperature setpoint, the controller 108 can reduce PCW supply flow or increase PCW supply flow temperature by employing the first heating system 410. For example, the controller 108 can employ the first heating system 410 to raise a temperature of the PCW supply fluid to increasing a temperature of the immersion fluid toward the global temperature setpoint.

In some examples, the controller 108 receives the global temperature setpoint (e.g., 35 degrees Celsius) and modulates a position of the first PCW control valve 318a (and/or the first heating system) so that the PCW supply fluid entering the first heat exchanger 308a is at a flowrate and/or temperature to provide the immersion fluid that exits the first heat exchanger 308a with a temperature corresponding to the global temperature setpoint.

For example, the controller 108 monitors a temperature of the immersion fluid that exits the first CDU 110 via the second IF temperature sensor 446 and uses this feedback to set a desired PCW supply fluid temperature at the PCW-side heat-exchanger inlet 404a (i.e., to achieve an immersion fluid temperature at the global temperature setpoint). The controller 108 compares a measured temperature of the immersion fluid at the first IF outlet 156, 322a via feedback signals from the second IF temperature sensor 446. For example, the controller 108 can operate the first PCW control valve 318a and/or the first PCW pump 314a and the first heater 316a of the first CDU 110 to either adjust (e.g., increase or decrease) a flowrate of the PCW supply fluid through the first heat exchanger 308a and/or activate the first heating system 410 to force heated PCW supply fluid through the first heat exchanger 308a (based on a comparison of the immersion fluid temperature at the first IF outlet 156, 322a and the global temperature setpoint).

To increase or raise the immersion fluid temperature in the immersion tank 114, the controller 108 moves the first PCW control valve 318a to a closed position (e.g., a fully closed) or a restricted position (e.g., partially closed position between 50% and 90% of a fully closed position) so that a less amount of the PCW supply fluid reaches the first heat exchanger 308a and/or activates (e.g., turns on) the first PCW pump 314a and the first heater 316a to increase a temperature of the PCW supply fluid circulating through the first heat exchanger 308a, reducing the amount of heat extracted from the immersion fluid in the first IF loop 306a. In some examples, the controller 108 closes the first PCW control valve 318a when the first PCW pump 314a and the first heater 316a are activated. By heating the PCW supply fluid to the first heat exchanger 308a, the immersion fluid and, thus, the tank temperature rises.

Conversely, allowing cooler PCW supply fluid to pass through the first heat exchanger 308a, the tank temperature is lowered. For example, to cool the immersion fluid (e.g., reduce a temperature of the immersion fluid to the immersion tank 114), the controller 108 moves the first PCW control valve 318a to an open position (e.g., a fully open position or between 50% and 90% of a fully open position) to allow a greater amount of PCW supply fluid through the first heat exchanger 308a and/or deactivates (e.g., turns off) the first PCW pump 314a and the first heater 316a. This allows cooler PCW supply fluid to flow through the first heat exchanger 308a without passing through the first heater 316a, thereby extracting more heat from the immersion fluid in the first IF loop 306a. A PCW fluid having a higher temperature can remove less heat from the immersion fluid. A PCW fluid having a lower temperature can remove more heat form the immersion fluid.

In some examples, the controller 108 controls the activation of the first heater 316a based on feedback from either of the IF temperature sensors 444, 446 associated with the first PCW loop 304a. More particularly, in some examples, one or more of the PCW temperature sensors 440, 442 provide measured temperature(s) to the controller 108 that are compared against a target temperature (e.g., a temperature setpoint). The controller 108 adjusts the power provided to the first heater 316a based on differences between the measured and target temperatures in substantially real time. In some examples, the controller 108 toggles the first PCW pump 314a and the first heater 316a between ON and OFF power states in a controlled manner (e.g., via pulse width modulation) to control the heating of the PCW fluid passing through the first heater 316a. In some examples, the controller 108 moves the first PCW control valve 318a to a closed position when the first PCW pump 314a is activated.

In some examples, the controller 108 modulates the first bypass valve 434 (e.g., to increase or decrease immersion fluid flowrate) based on feedback from the first IF flowrate sensor 328a. More particularly, in some examples, the first IF flowrate sensor 328a provides a measured flowrate to the controller 108 and the controller 108 compares the measured flowrate against a target flowrate (e.g., a flowrate setpoint, a user-defined setpoint). If the measured flowrate deviates from the target flowrate, the controller 108 adjusts a position (e.g., an opening) of the first bypass valve 434 based on differences between the measured and target flowrates in substantially real time. In some examples, the controller 108 is a programmable logic controller (PLC) that implements a proportional-integral-derivative (PID) feedback loop to control the flowrate of the immersion fluid. Thus, the flowrate through the first IF outlet 156, 322a can be adjusted independently of the immersion fluid temperature.

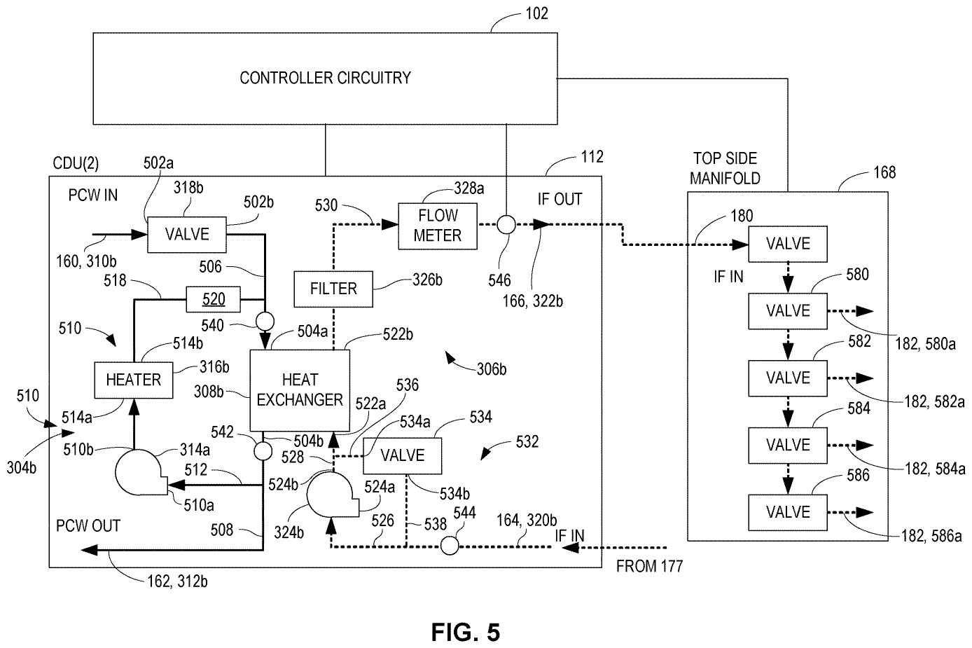

FIG. 5 is a schematic system of the second CDU 112 and the target manifold 168. The second CDU 112 provides or supplies temperature-controlled immersion fluid to the target manifold 168 based on a target manifold temperature setpoint. Importantly, the second CDU 112 operates independently of the first CDU 110 so that each unit can regulate a temperature and/or flowrate of the immersion fluid independently of one another.

To control temperature of the immersion fluid based on the target manifold temperature, the second CDU 112 features two closed loops: a second PCW loop 304b and a second IF loop 306b. A second heat exchanger 308b transfers energy between the PCW supply fluid in the second PCW loop 304b and the immersion fluid in the second IF loop 306b, enabling precise regulation of the immersion fluid temperature passing through the second heat exchanger 308b. The primary goal of the second CDU 112 is to regulate the temperature of the immersion fluid in the second IF loop 306b by exchanging heat with the PCW supply fluid in the second PCW loop 304b via the second heat exchanger 308b.

PCW supply fluid enters the second CDU 112 through the second PCW loop 304b. The second CDU 112 receives PCW supply fluid via the second PCW inlet 310b, 160 (e.g., an inlet valve 178) that couples to a PCW fluid supply source. A second PCW control valve 318b of the second CDU 112 regulates the flow of PCW supply fluid in the second PCW loop 304b. For example, the second PCW control valve 318b has a control valve inlet 502a that is fluidly coupled to the second PCW inlet 160, 310b and a first control valve outlet 502b that is fluidly coupled to a PCW-side heat exchanger inlet 504a (e.g., via a first PCW fluid line 506) of the second heat exchanger 308b. The second heat exchanger 308b is fluidly coupled to the second PCW outlet 162, 312b of the second CDU 112. For example, the second PCW outlet 162, 312b is fluidly coupled to a PCW-side heat exchanger outlet 504b (e.g., via a second PCW fluid line 508).

To adjust (e.g., raise or lower) a temperature of the PCW supply fluid, the second PCW loop 304b includes a second heating system 510 (e.g., a heating subloop). The second heating system 510 circulates the PCW supply fluid through the second heater 316b and the PCW-side of the second heat exchanger 308b. The second heating system 510 (e.g., a second heating system) has a second PCW pump 314b and a second heater 316b. The second PCW pump 314b circulates the PCW supply fluid from the PCW-side heat exchanger outlet 504b through the second heater 316b before returning it to the PCW-side heat exchanger inlet 504a of the second heat exchanger 308b, allowing the controller 108 to raise the temperature of the PCW supply fluid (e.g., if required by a control logic). The second inlet valve 318b and the second PCW pump 314b are positioned on the PCW-side of the second heat exchanger 308b. For example, the second PCW pump 314b includes a second PCW pump inlet 510a in fluid communication with the PCW-side heat exchanger outlet 504b (e.g., via a third fluid line 512). A second PCW pump outlet 510b of the second PCW pump 314b is fluidly coupled to a second heater inlet 514a of the second heater 316b (e.g., via a fourth fluid line 516), and a second heater outlet 514b of the second heater 316b is fluidly coupled to the PCW-side heat exchanger inlet 504a (e.g., via a fifth fluid line 518). The fifth fluid line 518 includes a valve 520 (e.g., a one-way valve) to prevent PCW supply fluid from flowing from the second PCW control valve 318b to the second heater 316b without first passing through the second heat exchanger 308b.

The second IF loop 306b circulates immersion fluid from the immersion tank 114 through an IF-side of the second heat exchanger 308b and returns the immersion fluid to the target manifold 168 via the second IF outlet 166, 322b based on the manifold target temperature setpoint of the controller 108. A second IF pump 324b draws fluid from the second IF inlet 164, 320b and directs the immersion fluid to an IF-side heat exchanger inlet 522a of the second heat exchanger 308b. For example, the second IF pump 324b includes a second IF pump inlet 524a fluidly couples to the second IF inlet 164, 320b of the second CDU 112 (e.g., via a first IF fluid line 526) and a second IF pump outlet 524b fluidly couples to the IF-side heat exchanger inlet 522a (e.g., via a second IF fluid line 528). An IF-side heat exchanger outlet 522b is fluidly coupled to the second IF outlet 166, 322b (e.g., via a third IF fluid line 530).

Additionally, the second IF loop 306b includes a second bypass loop 532 to tune a temperature and/or a flowrate of the immersion fluid flowing through the second IF loop 306a. For example, the second bypass loop 532 allows immersion fluid to route from the IF pump outlet 524b to the IF pump inlet 524a to adjust a flowrate of the immersion fluid through the second heat exchanger 308b. For instance, the second bypass loop 532 includes a second bypass valve 534 having a first bypass valve inlet 534a in fluid communication with the IF pump outlet 524b (e.g., via a fourth IF fluid line 536) and a first bypass valve outlet 534b in fluid communication with the IF pump inlet 524a (e.g., via a fifth IF fluid line 538). By adjusting flow through the second bypass valve 534 (e.g., by opening/closing this valve), the second CDU 112 can adjust a flowrate of the immersion fluid entering the second heat exchanger 308b and, thus, exiting the second IF outlet 166, 322b. For example, by opening the second bypass valve 534, a portion of the immersion fluid flowing from the IF pump outlet 524b diverts to the first IF fluid line 526 and/or the IF pump inlet 524a via the first IF fluid line 526, thereby reducing a flowrate and allowing fine-tuning of both temperature and/or flowrate (e.g., velocity) provided to the second IF outlet 166, 322b and the manifold 168. By closing (e.g., fully closing) the second bypass valve 534, immersion fluid flowing from the IF pump outlet 524b flows (e.g., fully) to the IF-side heat exchanger inlet 522a without portions of the immersion fluid diverting through the second bypass loop 532, thereby increasing a flowrate of the immersion fluid through the second heat exchanger 308b. After the second heat exchanger 308b, the immersion fluid passes through a second filter 326b (e.g., a 3-D printed or cartridge filter) that removes particulates from the immersion fluid and protects downstream components. A second IF flowrate sensor 328b is provided (e.g., installed) downstream of the second filter 326b. The second IF flow meter 328b continuously measures immersion fluid throughput of the second IF loop 306b in real-time. The immersion fluid that exits the second IF outlet 166, 322b flows to the target manifold 168 before reentering the second IF loop 306b of the second CDU 112 for the next cycle.

As shown in FIG. 5, the target manifold 168 includes a plurality of valves 510-516 coupled to respective ones of the manifold outlets 182 (FIG. 2C). Each of the valves 510-516 can be operated (e.g., by the controller 108 or manually) to adjust a flowrate at respective manifold outlets 182. The manifold outlets 182 are directed to or aligned with different distinct or targeted locations within the immersion tank 114. In some examples, the valves 510-516 are fluidly coupled to respective cold plates of electronic components of the server blade 132a as described above.

During normal operation, the second CDU 112 adjusts or regulates a temperature of the immersion fluid based on (e.g., to match) a target temperature setpoint (e.g., 25 degrees Celsius) for the target manifold 168. The energy exchange in the second IF loop 306b is driven by a flowrate and/or temperature of the PCW supply fluid circulating in the second PCW loop 304b. To implement the desired target temperature, the controller 108 controls (e.g., energizes or de-energizes) the second PCW pump 314b, the second heater 316b, the second IF pump 324b, and/or the second bypass valve 534 based on measured feedback or data provided to the controller 108.

To determine which components to control (e.g., activate or deactivate), the controller 108 receives data or feedback from one or more sensors. For example, the second CDU 112 includes a first PCW temperature sensor 540 (e.g., thermocouple) to measure PCW supply fluid temperature at the PCW-side heat exchanger inlet 504a, and a second PCW temperature sensor 542 (e.g., a thermocouple) to measure PCW supply fluid temperature at the PCW-side heat exchanger outlet 504b. In some examples, the second CDU 112 can include a second PCW flowrate sensor or flowmeter to detect or measure a fluid flowrate of the PCW supply fluid at the second PCW inlet 160. 310b. In some examples, the second IF loop 306b includes a first IF temperature sensor 544 to measure immersion fluid temperature at the IF-side heat exchanger inlet 522a and a second IF temperature sensor 546 to measure immersion fluid temperature at the second IF-side heat exchanger outlet 522b. The second IF flowrate sensor 328b provides a measured flowrate of the immersion fluid at the second IF outlet 166, 322b.

The controller 108 monitors immersion fluid temperature from the first IF temperature sensor 544 and/or the second IF temperature sensor 546 against the target manifold temperature setpoint (e.g., a user-defined setpoint). If the immersion fluid temperature increases above the manifold target temperature setpoint (e.g., 25 degrees Celsius), the second CDU 112 cools the immersion fluid by passing the PCW supply fluid in the second PCW loop 304b with a cooler temperature to remove or absorb excess energy from the immersion fluid in the second IF loop 306b. In some examples, if the immersion temperature is within a threshold (e.g., plus or minus 2 degrees, 5 degrees, etc.) of the target manifold temperature setpoint, the controller 108 can employ the second heating system 510 to maintain immersion fluid temperature at the second IF outlet 166, 322b steady, maintaining continuous cooling.

If the immersion fluid temperature falls below the target manifold temperature setpoint, the controller 108 can reduce PCW supply flow or employ the second heating system 510 to increase a temperature of the PCW supply fluid, thereby effectively increasing a temperature of the immersion fluid toward the target manifold temperature setpoint. For example, the controller 108 can employ the second heating system 510 to increase a temperature of the PCW supply fluid to increase a temperature of the immersion fluid toward the manifold target temperature setpoint.

In some examples, the controller 108 receives the target temperature setpoint (e.g., 25 degrees Celsius) and modulates a position of the second PCW control valve 318b (and/or the second heating system 510) so that the PCW supply fluid entering the second heat exchanger 308b is at a computed flowrate (and/or temperature) to provide the immersion fluid that exits the second heat exchanger 308b with a temperature corresponding to the manifold temperature setpoint.

For example, the controller 108 monitors a temperature of the immersion fluid that exits the second CDU 112 via the second IF temperature sensor 546 and uses this feedback to set a desired PCW supply fluid temperature at the PCW-side heat-exchanger inlet 504a (i.e., required to achieve an immersion fluid temperature at the manifold target temperature setpoint). The controller 108 compares a measured temperature of the immersion fluid at the second IF outlet 166, 322b via feedback signals from the second IF temperature sensor 546. For example, the controller 108 can operate the second PCW control valve 318b and/or the second PCW pump 314b and the second heater 316b of the second CDU 112 to either adjust (e.g., increase or decrease) a flowrate of the PCW supply fluid through the second heat exchanger 308b and/or activate the second heating system 510 to force heated PCW supply fluid through the second heat exchanger 308b (based on the immersion fluid temperature and the manifold temperature setpoint).

To increase or raise the immersion fluid temperature to the target manifold 168, the controller 108 moves the second PCW control valve 318b to a closed position (e.g., a fully closed) or a restricted position (e.g., partially closed position between 50% and 90% of a fully closed position) so that a lesser amount of PCW supply fluid reaches the second heat exchanger 308b and/or activates (e.g., turns on) the second PCW pump 314b and the second heater 316b to increase a temperature of the PCW supply fluid circulating through the second heat exchanger 308b, reducing the amount of heat extracted from the immersion fluid in the second IF loop 306b. In some examples, the controller 108 closes the second PCW control valve 318b when the second PCW pump 314b and the second heater 316b are activated. By heating the PCW supply fluid to the second heat exchanger 308b, the immersion fluid to the manifold 168 increases.

Conversely, allowing cooler PCW supply fluid to pass through the second heat exchanger 308b lowers or reduces the temperature of the immersion fluid to the manifold 168. For example, to cool the immersion fluid (e.g., reduce a temperature of the immersion fluid to the manifold 168), the controller 108 moves the second PCW control valve 318b to an open position (e.g., a fully open position or between 50% and 90% of a fully open position) to allow a greater amount of PCW supply fluid through the second heat exchanger 308b and/or deactivates (e.g., turns off) the second PCW pump 314b and the second heater 316b. This allows cooler PCW supply fluid to flow through the second heat exchanger 308b without passing through the second heater 316b, thereby extracting more heat from the immersion fluid in the second IF loop 306b. A PCW fluid having a higher temperature can remove less heat from the immersion fluid. A PCW fluid having a lower temperature can remove more heat form the immersion fluid.

In some examples, the controller 108 controls the activation of the second heater 316b based on feedback from either of the temperature sensors 544, 146 associated with the second PCW loop 304b. More particularly, in some examples, one or more of the PCW temperature sensors 540, 542 provide measured temperature(s) to the controller 108 that are compared against a target temperature (e.g., a temperature setpoint). The controller 108 adjusts the power provided to the second heater 316b based on differences between the measured and target temperatures in substantially real time. In some examples, the controller 108 toggles the second PCW pump 314b and the second heater 316b between ON and OFF power states in a controlled manner (e.g., via pulse width modulation) to control the heating of the PCW fluid passing through the second heater 316b. In some examples, the controller 108 moves the second PCW control valve 318b to a closed position when the second PCW pump 314b is activated.

In some examples, the controller 108 modulates the second bypass valve 534 (e.g., to increase or decrease immersion fluid flowrate) based on feedback from the second IF flowrate sensor 328b. More particularly, in some examples, the second IF flowrate sensor 328b provides a measured flowrate to the controller 108 and the controller 108 compares the measured flowrate against a target flowrate (e.g., a manifold flowrate setpoint, a user-defined setpoint). If the measured flowrate deviates from the target flowrate, the controller 108 adjusts a position (e.g., an opening) of the second bypass valve 534 based on differences between the measured and target flowrates in substantially real time. In some examples, the controller 108 is a programmable logic controller (PLC) that implements a proportional-integral-derivative (PID) feedback loop to control the flowrate of the immersion fluid. Thus, the flowrate through the second IF outlet 166, 322b can be adjusted independently of the immersion fluid temperature.

The controller 108 of the illustrated example controls the first CDU 110 independently from the second CDU 112. Thus, the first CDU 110 can provide immersion fluid having a first temperature (e.g., a global temperature) to the immersion tank 114 based on a first temperature setpoint (e.g., 35 degrees Celsius) and/or an immersion fluid flowrate based on a first flowrate set point (e.g., 1 liter per minute). Additionally, the second CDU 112 can provide immersion fluid to the manifold 168 having a second temperature (e.g., a target temperature) based on a second temperature setpoint (e.g., 25 degrees Celsius) and/or an immersion fluid flowrate based on a second flowrate setpoint (5 liters per minute). Thus, first CDU 110 can deliver immersion fluid to the immersion tank 114 having a first temperature and the second CDU 112 can deliver immersion fluid to the target manifold 168 having a second temperature that is different from the first temperature. Additionally or alternatively, the first CDU 110 can deliver immersion fluid to the immersion tank 114 having a first flowrate and the second CDU 112 can deliver immersion fluid to the target manifold 168 at a second flowrate different than the first flowrate.

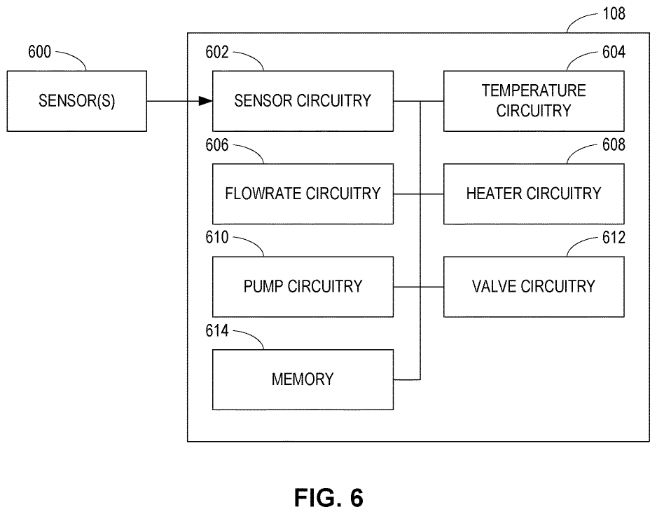

FIG. 6 is a block diagram of an example implementation of the controller 108 of the example cooling system 100 of FIGS. 1A-1C. The controller 108 (e.g., control circuitry) of FIG. 6 may be instantiated (e.g., creating an instance of, bring into being for any length of time, materializing, implement, etc.) by programmable circuitry. For example, programmable circuitry may be implemented by a Central Processor Unit (CPU) executing first instructions, a field programmable gate array, a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc. Additionally or alternatively, the controller 108 of FIG. 6 may be instantiated (e.g., creating an instance of, bring into being for any length of time, materialize, implement, etc.) by (i) an Application Specific Integrated Circuit (ASIC) and/or (ii) a Field Programmable Gate Array (FPGA) (e.g., another form of programmable circuitry) structured and/or configured in response to execution of second instructions to perform operations corresponding to the first instructions. It should be understood that some or all of the circuitry of FIG. 6 may, thus, be instantiated at the same or different times. Some or all of the circuitry of FIG. 6 may be instantiated, for example, in one or more threads executing concurrently on hardware and/or in series on hardware. Moreover, in some examples, some or all of the circuitry of FIG. 6 may be implemented by microprocessor circuitry executing instructions and/or FPGA circuitry performing operations to implement one or more virtual machines and/or containers.

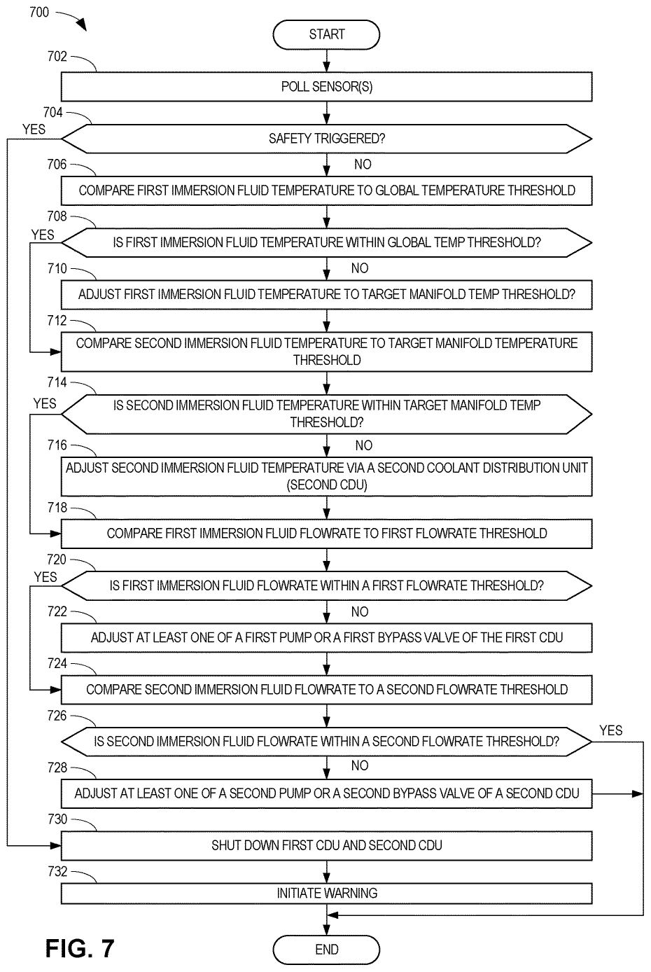

The controller 108 of the illustrated example includes example sensor circuitry 602 (e.g., a sensor module), example temperature circuitry 604 (e.g., a temperature detection module), example flowrate circuitry 606, example heater circuitry 608, example pump circuitry 610, example valve circuitry 612, example alert circuitry 614 and memory 616. In some examples, the controller 108 is instantiated by programmable circuitry executing instructions and/or configured to perform operations such as those represented by the flowchart of FIG. 7.

The sensor circuitry 602 polls or receives one or more signals from the sensors 600. In some examples, the sensor circuitry 602 analyzes and/or processes one or more signals from the sensors 600. The sensor circuitry 602 polls the sensors of the first CDU 110, the second CDU 112 and the immersion tank 114 for current process fluid conditions or characteristics and/or operating states of the components associated with the first CDU 110 and the second CDU 112. For example, the sensor circuitry 602 acquires raw data signals from one or more of the temperature sensors 440-446 of the first CDU 110, the temperature sensor 448 of the immersion tank 114, the temperature sensors 540-546 of the second CDU 112, operating positions of the PCW control valves 318a, 318b and the bypass valves 434, 534, measured flowrates from the IF flowrate sensors 328a, 328b, feedback signals indicative of operational states of the heaters 316a, 316b, the PCW pumps 314a, 314b, the IF pumps 324a, 324b, and/or any other suitable feedback signal(s). The sensor circuitry 602 analyzes, processes, filters, etc., these inputs to produce real-time or substantially real-time estimates of the first immersion fluid temperature of the first CDU 110, the second immersion fluid temperature of the second CDU 112, the immersion fluid temperature in the immersion tank 114, the first immersion flowrate of the first CDU 110, the second immersion fluid flowrate of the second CDU 112, temperature and/or flowrate of the PCW supply fluid in the first heat exchanger 308a and/or temperature and/or flowrate of the PCW supply fluid in the second heat exchanger 308b. In some examples, the sensor circuitry 602 is instantiated by programmable circuitry executing sensor polling instructions and/or configured to perform operations such as those represented by the flowchart of FIG. 7.

The temperature circuitry 604 detects multiple temperature conditions based on the temperature signals provided to or determined by the sensor circuitry 602. For example, the temperature circuitry 604 detects a temperature of the PCW and the temperature of the immersion fluid of the first CDU 110, the PCW and the temperature of the immersion fluid of the second CDU 112 and/or the temperature of the immersion fluid in the immersion tank 114. Additionally, the temperature circuitry 604 compares the measured temperature conditions to one or more threshold temperatures stored, for example, in memory 616. For example, the temperature circuitry 604 receives, retrieves and/or otherwise obtains the threshold temperature values from memory 616. For example, the temperature circuitry 604 retrieves, obtains or otherwise requests from memory 616 the global temperature setpoint and/or the manifold target temperature threshold. For example, the global temperature setpoint and/or the target manifold temperature setpoint can be provided via the user interface or the display 148 of the controller 108 and stored in memory 616. In some examples, the temperature circuitry 604 is instantiated by programmable circuitry executing temperature comparison instructions and/or configured to perform operations such as those represented by the flowchart of FIG. 7.

In some examples, the temperature circuitry 604 calculates control signals using a PID algorithm to maintain each CDU's target immersion fluid temperature within ±X °C (e.g., ±5 °C) of its setpoint. For example, the temperature circuitry 604 regulates the immersion fluid temperature of the first CDU 110 based on the global temperature setpoint (e.g., within 5 degrees Celsius of the global target setpoint) and regulates the immersion fluid temperature of the second CDU 112 based on the target manifold temperature setpoint (e.g., within 5 degrees Celsius of the target manifold temperature). The temperature circuitry 604 (e.g., PLC logic) includes a closed-loop temperature regulation loop that allows the first CDU 110 to heat or cool its immersion fluid supply independently of the second CDU 112. Thus, each CDU 110, 112 can provide immersion fluid having different temperatures.

For example, the temperature circuitry 604 receives a feedback signal from the temperature sensor 448 of the immersion tank 114 representative of a measured global or overall temperature of the immersion fluid in the immersion tank 114. Additionally, the temperature circuitry 604 compares the measured global temperature against a global temperature setpoint. If the measured immersion temperature (e.g., from the feedback signal of the temperature sensor 448) deviates the global temperature setpoint, the temperature circuitry 604 provides a command or sets a flag for the heater circuitry 608, the pump circuitry 610 and the valve circuitry 612 based on the conditions of the PCW and the immersion fluid of the first CDU 110. For example, the command and/or the flag set by the temperature circuitry 604 can include instructions or commands to the first CDU 110 to provide immersion fluid having either an increased temperature or a decreased temperature. For example, the command and/or the first flag set by the temperature circuitry 604 can include instructions or commands for the heater circuitry 608 to turn off or deactivate the first heater 316a, deactivate the first PCW pump 314a and/or increase an opening of the first PCW control valve 318a (i.e., to allow cooler temperature PCW in the first heat exchanger 308a). In some examples, the command and/or the flag set by the temperature circuitry 604 can include instructions or commands for the heater circuitry 608 to turn on or activate the first heater 316a, activate the first PCW pump 314a and/or decrease or close an opening of the first PCW control valve 318a (i.e., to restrict or prevent cooler temperature PCW in the first heat exchanger 308a).

In some examples, the temperature circuitry 604 receives one or more signals from the first PCW temperature sensor 440 and/or the second PCW temperature sensor 442 to determine a temperature of the PCW flowing through the first heat exchanger 308a of the first CDU 110. In some cases, the temperature circuitry 604 measures a difference between a first temperature reading by the first PCW temperature sensor 440 and a second temperature reading by the second PCW temperature sensor 442 to detect the PCW temperature. Likewise, the temperature circuitry 604 receives one or more signals from the first IF temperature sensor 444 and/or the second IF temperature sensor 446 to determine a temperature of the immersion fluid flowing through the first heat exchanger 308a of the first CDU 110. In some cases, the temperature circuitry 604 measures a difference between a first temperature reading provided by the first IF temperature sensor 444 and a second temperature reading provided by the second IF temperature sensor 446 to detect the immersion fluid temperature. Based on the difference between the PCW supply fluid temperature and the immersion fluid temperature, the temperature circuitry 604 determines if the PCW supply fluid requires temperature adjustment to achieve an immersion fluid having a temperature within the global temperature threshold. In some examples, the temperature circuitry 604 determines (e.g., from stored data (e.g., a look-up table) in memory 616) a temperature of the PCW supply fluid needed to adjust a temperature of the immersion fluid flowing across the first heat exchanger 308a based on characteristics of the PCW supply fluid, the immersion fluid and the first heat exchanger 308a.

In some examples, the temperature circuitry 604 measures or monitors an immersion fluid temperature (e.g., a temperature feedback signal of the temperature sensor 446 indicative of the immersion fluid temperature) and compares the immersion fluid exiting the first CDU 110 to the global temperature setpoint to determine if the immersion fluid temperature is within the global temperature threshold. Based on the comparison, the temperature circuitry 604 provides a first command or sets a first flag for the heater circuitry 608, the pump circuitry 610 and the valve circuitry 612.

Likewise, the temperature circuitry 604 monitors immersion fluid temperature of the second CDU 112 (e.g., exiting the second CDU 112) by comparing the immersion fluid temperature of the second CDU 112 to the target manifold temperature setpoint (e.g., retrieved from memory 616). To adjust or maintain the temperature of the immersion fluid of the second CDU 112, the temperature circuitry 604 detects a temperature of the PCW and the temperature of the immersion fluid in the second CDU 112. For example, the temperature circuitry 604 receives one or more signals from the first PCW temperature sensor 540 and/or the second PCW temperature sensor 542 to determine a temperature of the PCW flowing through the second heat exchanger 308b of the second CDU 112. In some cases, the temperature circuitry 604 measures a difference between a first temperature reading provided by the first PCW temperature sensor 540 and a second temperature reading provided by the second PCW temperature sensor 542 to detect the PCW temperature. Likewise, the temperature circuitry 604 receives one or more signals from the first IF temperature sensor 544 and/or the second IF temperature sensor 546 to determine a temperature of the immersion fluid flowing through the second heat exchanger 308b of the second CDU 112. In some cases, the temperature circuitry 604 measures a difference between a first temperature reading provided by the first IF temperature sensor 544 and a second temperature reading provided by the second IF temperature sensor 546 to detect the immersion fluid temperature. Based on the comparison between the immersion fluid temperature and the target manifold temperature setpoint, the temperature circuitry 604 commands or instructs (e.g., sets a flag for) the heater circuitry 608, the pump circuitry 610 and/or the valve circuitry 612.

For example, if the immersion fluid temperature exceeds the target manifold temperature threshold, the heater circuitry 608 reduces power to and/or deactivates the second heater 316b, the pump circuitry 610 deactivates the second PCW pump 314b, and/or the valve circuitry 612 commands or causes the second PCW control valve 318b to move to an open position to increase PCW supply fluid flow to the second heat exchanger 308b of the second CDU 112. Conversely, if the immersion fluid temperature is less than the target manifold temperature threshold, the heater circuitry 608 increases power to and/or activates the second heater 316a, the pump circuitry 610 activates the second PCW pump 314b, and/or the valve circuitry 612 commands or causes the second PCW control valve 318b to move to a closed or restricted position to decrease or prevent PCW supply fluid flow to the second heat exchanger 308b of the second CDU 112. In some examples, the temperature circuitry 604 determines (e.g., from stored data (e.g., a look-up table) in memory 616) a temperature of the PCW supply fluid needed to adjust a temperature of the immersion fluid flowing across the second heat exchanger 308b based on characteristics of the PCW supply fluid, the immersion fluid, and the second heat exchanger 308b.

The flowrate circuitry 606 detects multiple flowrate conditions based on the flowrate signals provided to or determined by the sensor circuitry 602. For example, the flowrate circuitry 606 detects a flowrate of the PCW and/or a flowrate of the immersion fluid of the first CDU 110, and/or a flowrate of the PCW and/or a flowrate of the immersion fluid of the second CDU 112. Additionally, the flowrate circuitry 606 compares the measured flowrates to one or more threshold flowrates stored, for example, in memory 616. For example, the flowrate circuitry 606 receives, retrieves and/or otherwise obtains the threshold flowrate values from memory 616. In some examples, the flowrate circuitry 606 determines variable-frequency-drive pump speeds for the PCW pumps 314a, 314b, the IF pumps 324a, 324b, and/or the valve positions of the PCW control valves 318a, 318b and the bypass valves 434, 534 to achieve specified flowrate targets. In some examples, the flowrate circuitry 606 is instantiated by programmable circuitry executing flowrate comparison instructions and/or configured to perform operations such as those represented by the flowchart of FIG. 7.

The heater circuitry 608 adjusts operation of the first heater 316a of the first CDU 110 and/or the second heater 316b of the second CDU 112. For example, the heater circuitry 608 adjusts operation of the first heater 316a independently from the second heater 316b. In some examples, the heater circuitry 608 adjusts (e.g., increases or decreases) power to the first heater 316a and/or the second heater 316b. In some examples, the heater circuitry 608 activates (e.g., turns on) or deactivates (e.g., turns off) (e.g., generates on/off or duty-cycle commands to) the first heater 316a and/or the second heater 316b. In some examples, the heater circuitry 608 is instantiated by programmable circuitry executing heater activation instructions and/or configured to perform operations such as those represented by the flowchart of FIG. 7.

The pump circuitry 610 adjusts operation of the first PCW pump 314a and/or the first IF pump 324a of the first CDU 110 and/or the second PCW pump 314b and/or the second IF pump 324b of the second CDU 112. For example, the pump circuitry 610 adjusts operation of the pumps 314a, 314b, 324a and 324b independently of each other. In some examples, the pump circuitry 610 adjusts (e.g., increases or decreases) power to the first PCW pump 314a, the first IF pump 324a, the second PCW pump 314b and/or the second IF pump 324b. In some examples, the pump circuitry 610 activates (e.g., turns on) or deactivates (e.g., turns off) (e.g., generates on/off or duty-cycle commands to) the first PCW pump 314a, the first IF pump 324a, the second PCW pump 314b and/or the second IF pump 324b. In some examples, the pump circuitry 610 is instantiated by programmable circuitry executing heater activation instructions and/or configured to perform operations such as those represented by the flowchart of FIG. 7.

The valve circuitry 612 controls, operates or cause adjustments to positions of the valves 318a, 318b 434, 534 of the first CDU 110 and the second CDU 112. Specifically, the valve circuitry 612 operates each of the valves 318a, 318b 434, 534 independently of each other. For example, the valve circuitry 612 commands, instructs and/or otherwise causes the first PCW control valve 318a, the first bypass valve 434, the second PCW control valve 318b and/or the second bypass valve 534 to move between an open position (e.g., a fully open position) and a closed position (e.g., a fully closed position). In some examples, the valve circuitry 612 generates one/off or duty-cycle commands to the PCW control valves 318a, 318b and/or the bypass valves 434, 534. In some examples, the valves 510-516 of the manifold can be control valves that can be operated by the valve circuitry 612. In some examples, the valve circuitry 612 is instantiated by programmable circuitry executing control valve instructions and/or configured to perform operations such as those represented by the flowchart of FIG. 7.

The alert circuitry 614 evaluates safety interlocks (e.g., an emergency shut-off status, leak detection, an over-temperature condition) before any actuation commands are issued. For example, the alert circuitry 614 detects and/or presents one or more warning signals representative of an error or leak condition. In some examples, the alert circuitry 614 initiates a warning or alert when monitored parameter(s) (e.g., temperature, flowrate, etc.) exceed pre-defined safety limits. For example, the alert circuitry 614 can detect abnormal flowrate and/or temperature readings that can be representative of, for example, leaks, flow blockages, etc. In some examples, the alert circuitry 614 can command or override the heater circuitry 608, the pump circuitry 610 and the valve circuitry 612 to shut down the pumps 314a, 314b, 324a, 324b, the heaters 316a, 316b, and/or the valves 318a, 318b, 434, 534. In some examples, the alert circuitry 614 detects if an emergency shut-off switch of the controller 108 (e.g., provided by a user interface of the controller 108) is in a triggered state. In some examples, the alert circuitry 614 triggers an emergency off command if limits are exceeded. Because each of the first CDU 110 and the second CDU 112 is isolated, a fault in one of the CDUs 110, 112 (e.g., a leak or blockage) does not directly affect the other CDU 110, 112. In some examples, the alert circuitry 614 can present a warning signal via a display, a speaker, the indicator lights 338 (e.g., an light emitting diode (LED) indicator) of the first CDU 110, the second CDU 112 and/or display 148 of the controller 108, a remote server or control room, and/or other device. For example, the alert circuitry 614 can employ visual indicators and/or audible alarms to inform maintenance or users of a potential leak, flow blockage or other issue. In some examples, the alert circuitry 614 includes. All alert events of the alert circuitry 614 are recorded in memory 616. In some examples, the alert circuitry 614 is instantiated by programmable circuitry executing warning instructions and/or configured to perform operations such as those represented by the flowchart of FIG. 4.

The memory 616 stores firmware, configuration parameters (e.g., global temperature setpoint, target manifold temperature setpoint, control valve positions), diagnostic logs, etc. The memory also supports over-the-air (OTA) firmware updates that can adjust logic without cooling system downtime.

While an example manner of implementing the controller 108 of FIGS. 1A-1C is illustrated in FIG. 6, one or more of the elements, processes, and/or devices illustrated in FIG. 6 may be combined, divided, re-arranged, omitted, eliminated, and/or implemented in any other way. Further, the example sensor circuitry 602, the example temperature circuitry 604, the example flowrate circuitry 606, the example heater circuitry 608, the example pump circuitry 610, the example valve circuitry 612, the example alert circuitry 614 and/or, more generally, the example controller 108 of FIG. 6, may be implemented by hardware alone or by hardware in combination with software and/or firmware. Thus, for example, any of the example sensor circuitry 602, the example temperature circuitry 604, the example flowrate circuitry 606, the example heater circuitry 608, the example pump circuitry 610, the example valve circuitry 612, the example alert circuitry 614 and/or, more generally, the example controller 108 of FIG. 6, could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine readable instructions (e.g., firmware or software). Further still, the example controller 108 of FIG. 6 may include one or more elements, processes, and/or devices in addition to, or instead of, those illustrated in FIG. 6, and/or may include more than one of any or all of the illustrated elements, processes and devices.

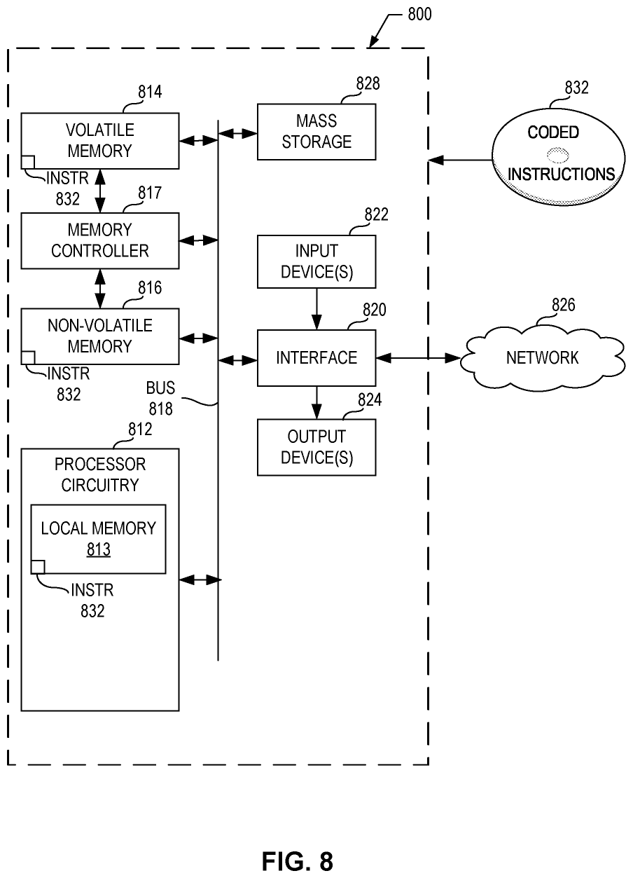

A flowchart representative of example machine readable instructions, which may be executed by programmable circuitry to implement and/or instantiate the controller of FIG. 6 and/or representative of example operations which may be performed by programmable circuitry to implement and/or instantiate the controller 108 of FIG. 6, is shown in FIG. 7. The machine readable instructions may be one or more executable programs or portion(s) of one or more executable programs for execution by programmable circuitry such as the programmable circuitry 812 shown in the example processor platform 800 discussed below in connection with FIG. 8 and/or may be one or more function(s) or portion(s) of functions to be performed by the example programmable circuitry (e.g., an FPGA). In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIG. 7, many other methods of implementing the example controller 108 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). As used herein, programmable circuitry includes any type(s) of circuitry that may be programmed to perform a desired function such as, for example, a CPU, a GPU, a VPU, and/or an FPGA. The programmable circuitry may include one or more CPUs, one or more GPUs, one or more VPUs, and/or one or more FPGAs located in the same package (e.g., the same integrated circuit (IC) package or in two or more separate housings), one or more CPUs, GPUs, VPUs, and/or one or more FPGAs in a single machine, multiple CPUs, GPUs, VPUs, and/or FPGAs distributed across multiple servers of a server rack, and/or multiple CPUs, GPUs, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above. As used herein, the term “circuitry” refers to at least one “circuit.” Thus, circuitry refers to a circuit or a system of circuits. As used herein, programmable circuitry includes and/or corresponds to at least one programmable circuit.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIG. 7 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 7 is a flowchart representative of example machine readable instructions and/or example operations 700 that may be executed, instantiated, and/or performed by programmable circuitry to adjust immersion fluid temperature of the first CDU 110 and the second CDU 112. The example machine-readable instructions and/or the example operations 700 of FIG. 7 begin at block 702, at which the sensor circuitry 602 polls (e.g., receives) one or more signals from the sensors 600 corresponding to characteristic(s) of the cooling system 100 and/or operational states of components of the cooling system 100. For example, the sensor circuitry 602 receives temperature signals from the temperature sensors 440-446, 448, 540-546, flowrate signals from the IF flowrate sensors 328a, 328b, and operational states of the PCW control valves 318a, 318b, the bypass valves 434, 534, the heaters 316a, 316b, the PCW pumps 314a, 314b, the IF pumps 324a, 324b of the first CDU 110 and the second CDU 112 and/or any other suitable feedback signal(s). For example, the sensor circuitry 602 can receive signals from the temperature sensors 440-448 and the IF flowrate sensors 328a, 328b to determine of immersion fluid temperature of the immersion tank 114, PCW temperature and flowrate of the PCW in the first PCW loop 304a of the first CDU 110, the immersion fluid temperature and/or flowrate of the immersion fluid in the first IF loop 306a of the first CDU 110, and/or the immersion fluid temperature of the second CDU 112.

At block 704, the alert circuitry 614 determines if safety issue(s) are identified. If at block 704 a safety issue is not identified (block 704; NO), the temperature circuitry 604 compares a measured immersion fluid temperature to the global temperature threshold (block 706). For example, the temperature circuitry 604 receives a feedback signal from the temperature sensor 448 of the immersion tank 114 representative of a global or overall temperature of the immersion fluid in the immersion tank 114 and compares the measured global temperature against a global temperature setpoint.

At block 708, the temperature circuitry 604 determines if the immersion fluid temperature is within a global temperature threshold (e.g., the global temperature setpoint plus or minus X degrees). For example, the temperature circuitry 604 compares the sensor reading of the temperature sensor 448 of the immersion tank 114 and/or the sensor reading of the second IF temperature sensor 446 of the first CDU 110 and compares one or both of these values with the global temperature threshold to determine if the immersion fluid associated with the immersion tank 114 and/or the first CDU 110 is within the global temperature threshold.

If at block 708 the first immersion temperature is not within the global temperature threshold (block 708; NO), the temperature circuitry 604 causes adjustment of the immersion fluid temperature of the first CDU 110 (block 710). For example, the temperature circuitry 604 can provide one or more commands for the heater circuitry 608, the pump circuitry 610 and/or the valve circuitry 612 based on the conditions of the PCW and the immersion fluid of the first CDU 110. For example, the temperature circuitry 604 can instruct or command to the first CDU 110 to provide immersion fluid having either an increased temperature or a decreased temperature. In some examples, the temperature circuitry 604 measures a difference between a first temperature reading provided by the first PCW temperature sensor 440 and a second temperature reading provided by the second PCW temperature sensor 442 to detect the PCW temperature and one or more signals from the first IF temperature sensor 444 and/or the second IF temperature sensor 446 to determine a temperature of the immersion fluid flowing through the first heat exchanger 308a of the first CDU 110 and commands the heater circuitry 608, the pump circuitry 610 and/or the valve circuitry 612 based on this information.

For example, in response to determining that the measured immersion fluid exceeds the global temperature threshold (e.g., is greater than an upper limit of the global temperature threshold), the temperature circuitry 604 determines that cooler temperature PCW is needed in the first heat exchanger 308a For example, the temperature circuitry 604 can include instructions or commands for the heater circuitry 608 to turn off or deactivate the first heater 316a, deactivate the first PCW pump 314a and/or increase an opening of the first PCW control valve 318a. Likewise, in response to determining that the immersion fluid does not exceed the global temperature threshold (e.g., is lower than a lower limit of the global temperature threshold), the temperature circuitry 604 determines that warmer temperature PCW is needed in the first heat exchanger 308a. For example, the temperature circuitry 604 can include instructions or commands for the heater circuitry 608 to turn on or activate the first heater 316a, activate the first PCW pump 314a and/or decrease an opening or fully close the first PCW control valve 318a.

If at block 708 the temperature circuitry 604 determines that the immersion fluid is within the global temperature threshold (block 708; YES), the temperature circuitry 604 maintains the operational state of the first CDU 110 (e.g., maintains the first PCW control valve 318a, the first PCW pump 314a and the first heater 316a at their respective current operating positions) and the operation 700 moves to block 712.

At block 714, the temperature circuitry 604 compares the second immersion fluid temperature to a target manifold temperature threshold. For example, the temperature circuitry 604 receives or obtains a signal from the second IF temperature sensor 446 representative of the temperature of the immersion fluid exiting the second CDU 112 and compares the measured temperature with the target manifold temperature threshold (e.g., the manifold temperature setpoint plus or minus X degrees).

If at block 714 the second immersion temperature is not within the target manifold temperature threshold (block 714; NO), the temperature circuitry 604 causes adjustment of the immersion fluid temperature of the second CDU 112 (block 716). For example, the temperature circuitry 604 can provide one or more commands for the heater circuitry 608, the pump circuitry 610 and/or the valve circuitry 612 based on the conditions of the PCW and the immersion fluid of the second CDU 112. For example, the temperature circuitry 604 can instruct or command to the second CDU 112 to provide immersion fluid having either an increased temperature or a decreased temperature. In some examples, the temperature circuitry 604 measures a difference between a first temperature reading provided by the first PCW temperature sensor 540 and a second temperature reading provided by the second PCW temperature sensor 542 to detect the PCW temperature and one or more signals from the first IF temperature sensor 544 and/or the second IF temperature sensor 546 to determine a temperature of the immersion fluid flowing through the second heat exchanger 308b of the second CDU 112 and commands the heater circuitry 608, the pump circuitry 610 and/or the valve circuitry 612 based on this information.

For example, in response to determining that the measured immersion fluid exceeds the target manifold temperature threshold (e.g., is greater than an upper limit of the target manifold temperature threshold), the temperature circuitry 604 determines that cooler temperature PCW is needed in the second heat exchanger 308b. For example, the temperature circuitry 604 can instruct or command the heater circuitry 608 to deactivate the second heater 316b, deactivate the second PCW pump 314b and/or increase an opening of the second PCW control valve 318b. Likewise, in response to determining that the immersion fluid does not exceed the target manifold temperature threshold (e.g., is lower than a lower limit of the target manifold temperature threshold), the temperature circuitry 604 determines that warmer temperature PCW is warranted in the second heat exchanger 308b. For example, the temperature circuitry 604 can instruct or command the heater circuitry 608 to activate the second heater 316b, activate the second PCW pump 314b and/or decrease an opening or close the second PCW control valve 318b.

If at block 714 the temperature circuitry 604 determines that the immersion fluid is within the target manifold temperature threshold (block 714; YES), the temperature circuitry 604 maintains the operational state of the second CDU 112 (e.g., maintains the second PCW control valve 318b, the second PCW pump 314b and the second heater 316b at their respective current operating positions) and the operation 700 moves to block 718.

At block 718, the flowrate circuitry 606 compares the first immersion fluid flowrate with a first flowrate threshold. For example, the flowrate circuitry 606 measures the flowrate of the first immersion fluid of the first CDU 110 via the first IF flowrate sensor 328a.

At block 720, the flowrate circuitry 606 determines if the measured flowrate of the immersion fluid of the first CDU 110 is within a first flowrate threshold. For example, the flowrate circuitry 606 compares the measured flowrate value from the first IF flowrate sensor 328a to the first flowrate threshold stored in memory 616.

If at block 720 the first immersion flowrate is not within the first flowrate threshold (block 720; NO), the flowrate circuitry 606 adjusts a flowrate of the first CDU 110 (block 722). For example, the flowrate circuitry 606 commands or causes adjustment of the first IF pump 324a and/or the first bypass valve 434.

For example, if the measured flowrate exceeds the first flowrate threshold (e.g., the measured flowrate is greater than an upper limit of the first flowrate threshold), the flowrate circuitry 606 reduces speed and/or power to the first IF pump 324a and/or opens the first bypass valve 434. For example, reducing the pump speed reduces the flowrate through the first IF pump 324a. Additionally or alternatively, by opening the first bypass valve 434, a portion of the immersion fluid that exits the pump outlet 424b of the first IF pump 324a diverts through the first bypass valve 434 and returns to the pump inlet 424a of the first IF pump 324a, thereby reducing a flowrate of the immersion fluid passing through the first heat exchanger 308a and, thus, flowing to the first IF outlet 156, 322a.

For example, if the measured flowrate is less than the first flowrate threshold (e.g., the measured flowrate is less than a lower limit of the first flowrate threshold), the flowrate circuitry 606 increases speed and/or power of the first IF pump 324a and/or moves a position of the first bypass valve 434 to a closed (e.g., fully closed) or restricted (e.g., 10 percent of fully closed) position. For example, by closing or restricting flow through the first bypass valve 434, all or most of the immersion fluid that exits the pump outlet 424b of the first IF pump 324a flows through the first heat exchanger 308a. In other words, none (or less amount) of the immersion fluid that exits the pump outlet 424b of the first IF pump 324a diverts through the first bypass valve 434 and returns to the pump inlet 424a of the first IF pump 324a, thereby increasing a flowrate of the immersion fluid passing through the first heat exchanger 308a and, thus, flowing to the first IF outlet 156, 322a.

If at block 720 the flowrate circuitry 606 determines that the first immersion fluid is within the first flowrate threshold (block 720; YES), the flowrate circuitry 606 maintains the operational state of the first CDU 110 (e.g., maintains current operational states of the first bypass valve 434 and the first IF pump 324a), and the operation 700 moves to block 724.

At block 724, the flowrate circuitry 606 compares the measured flowrate of the immersion fluid of the second CDU 112 is within a second flowrate threshold. For example, the flowrate circuitry 606 compares the measured flowrate value from the second IF flowrate sensor 328b to the second flowrate threshold stored in memory 616.

At block 726, the flowrate circuitry 606 determines if the measured flowrate of the immersion fluid of the second CDU 112 is within a second flowrate threshold.

If at block 726 the first immersion flowrate is not within the first flowrate threshold (block 726; NO), the flowrate circuitry 606 adjusts a flowrate of the second CDU 112 (block 728). For example, the flowrate circuitry 606 commands or causes adjustment of the second IF pump 324b and/or the second bypass valve 534.

For example, if the measured flowrate exceeds the second flowrate threshold (e.g., the measured flowrate is greater than an upper limit of the second flowrate threshold), the flowrate circuitry 606 reduces power and/or speed of the second IF pump 324b and/or opens the second bypass valve 534. For example, reducing the pump speed reduces the flowrate through the second IF pump 324b. Additionally or alternatively, by opening the second bypass valve 534, a portion of the immersion fluid that exits the pump outlet 524b of the second IF pump 324b diverts through the second bypass valve 534 and returns to the pump inlet 524a of the second IF pump 324b, thereby reducing a flowrate of the immersion fluid passing through the second heat exchanger 308b and, thus, flowing to the second IF outlet 166, 322b.

For example, if the measured flowrate is less than the second flowrate threshold (e.g., the measured flowrate is less than a lower limit of the second flowrate threshold), the flowrate circuitry 606 increases speed and/or power to the second IF pump 324b and/or moves a position of the first bypass valve 434 to a closed (e.g., fully closed) or restricted (e.g., 10 percent of fully closed) position. For example, increasing pump speed increases a flowrate through the second IF pump 324b. Additionally or alternatively, by closing or restricting flow through the second bypass valve 534, all or most of the immersion fluid that exits the pump outlet 524b of the second IF pump 324b flows through the second heat exchanger 308b. In other words, none (or less amount) of the immersion fluid exiting the pump outlet 524b of the second IF pump 324b diverts through the second bypass valve 534 and returns to the pump inlet 424a of the second IF pump 324b, thereby increasing a flowrate of the immersion fluid passing through the second heat exchanger 308b and, thus, flowing to the second IF outlet 166, 322b. After adjustment at block 728, the operation 700 ends.

If at block 726 the flowrate circuitry 606 determines that the first immersion fluid is within the second flowrate threshold (block 726; YES), the flowrate circuitry 606 maintains the operational state of the second CDU 112 (e.g., maintains current operational states of the second bypass valve 534 and the second IF pump 324b), and the operation 700 ends.

Returning to block 704, if a safety issue is identified by the alert circuitry 614 (block 704; YES), the alert circuitry 614 shuts down operation of (e.g., turns off power to) the first CDU 110 and/or the second CDU 112 (block 730). The alert circuitry 614 initiates a warning (block 732) and the operation 700 ends. For example, the alert circuitry 614 illuminates one or more indicator lights 338 of the first CDU 110 and/or the second CDU 112. In some examples, the alert circuitry 614 initiates one or more alarms (e.g., indicator lights, audible warnings, etc.) via the display 148 of the controller 108. In some examples, the alert circuitry 614 polls the emergency off switch of the controller 108 to determine if a safety issue is identified.

FIG. 8 is a block diagram of an example programmable circuitry platform 800 structured to execute and/or instantiate the example machine-readable instructions and/or the example operations of FIG. 7 to implement the controller 108 of FIG. 6. The programmable circuitry platform 800 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a wearable device, or any other type of computing and/or electronic device.

The programmable circuitry platform 800 of the illustrated example includes programmable circuitry 812. The programmable circuitry 812 of the illustrated example is hardware. For example, the programmable circuitry 812 can be implemented by one or more integrated circuits, logic circuits, FPGAs, microprocessors, CPUs, GPUs, VPUs, DSPs, and/or microcontrollers from any desired family or manufacturer. The programmable circuitry 812 may be implemented by one or more semiconductor based (e.g., silicon based) devices. In this example, the programmable circuitry 812 implements the example sensor circuitry 602, the example temperature circuitry 604, the example flowrate circuitry 606, the example heater circuitry 608, the example pump circuitry 610, the example valve circuitry 612, the example alert circuitry 614 and/or, more generally, the example controller 108 of FIG. 6.

The programmable circuitry 812 of the illustrated example includes a local memory 813 (e.g., a cache, registers, etc.). The programmable circuitry 812 of the illustrated example is in communication with main memory 814, 816, which includes a volatile memory 814 and a non-volatile memory 816, by a bus 818. The volatile memory 814 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 816 may be implemented by flash memory and/or any other desired type of memory device. Access to the main memory 814, 816 of the illustrated example is controlled by a memory controller 817. In some examples, the memory controller 817 may be implemented by one or more integrated circuits, logic circuits, microcontrollers from any desired family or manufacturer, or any other type of circuitry to manage the flow of data going to and from the main memory 814, 816.

The programmable circuitry platform 800 of the illustrated example also includes interface circuitry 820. The interface circuitry 820 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 822 are connected to the interface circuitry 820. The input device(s) 822 permit(s) a user (e.g., a human user, a machine user, etc.) to enter data and/or commands into the programmable circuitry 812. The input device(s) 822 can be implemented by, for example, an audio sensor, a microphone, a camera (still or video), a keyboard, a button, a touchscreen, an isopoint device, and/or a voice recognition system.

One or more output devices 824 are also connected to the interface circuitry 820 of the illustrated example. The output device(s) 824 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, and/or speaker. The interface circuitry 820 of the illustrated example, thus, typically includes a graphics driver card, a graphics driver chip, and/or graphics processor circuitry such as a GPU.

The interface circuitry 820 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 826. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 800 of the illustrated example also includes one or more mass storage discs or devices 828 to store firmware, software, and/or data. Examples of such mass storage discs or devices 828 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine readable instructions 832, which may be implemented by the machine readable instructions of FIG. 7, may be stored in the mass storage device 828, in the volatile memory 814, in the non-volatile memory 816, and/or on at least one non-transitory computer readable storage medium such as a CD or DVD which may be removable.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “substantially,” “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

Example methods, apparatus, systems, and articles of manufacture directed to immersion cooling systems and related methods for are disclosed. Examples disclosed herein provided targeted cooling for certain regions of immersion tanks Further examples and combinations thereof include the following:
Example 1 includes an apparatus comprising an immersion tank having a first inlet and a second inlet different than the first inlet, a first coolant distribution unit (CDU) fluidly coupled to the first inlet of the immersion tank, a second coolant distribution unit (CDU) fluidly coupled to the second inlet of the immersion tank, a controller to cause the first CDU to provide immersion fluid to the first inlet of the immersion tank at a first temperature that is within a first temperature threshold of a global temperature setpoint provided to the controller, and cause the second CDU to provide immersion fluid to the second inlet of the immersion tank at a second temperature that is within a second temperature threshold of a target manifold setpoint provided to the controller, and an equipment rack, wherein the immersion tank, the first CDU, the second CDU and the controller are coupled to the equipment rack.
Example 2 includes the apparatus of example 1, wherein the first CDU provides the first immersion fluid to a global distribution grate of the immersion tank, and the second CDU provides the second immersion fluid to a target manifold coupled to the immersion tank, the target manifold in fluid communication with one or more components of a server blade immersed in the immersion tank.
Example 3 includes the apparatus of any one or more of examples 1-2, wherein the first temperature is different from the second temperature.
Example 4 includes the apparatus of any one or more of examples 1-3, further including one or more infrastructure components and a hoist system, the one or more infrastructure components and the hoist system coupled to the equipment rack.
Example 5 includes the apparatus of example 4, wherein the equipment rack includes an upper support frame, a base support frame, and a side support frame extending between the upper support frame and the base support frame.
Example 6 includes the apparatus of example 5, wherein the upper support frame includes the hoist system to removably couple an electronic component from a cavity of the immersion tank.
Example 7 includes the apparatus of example 6, wherein the hoist system includes a hoist and a trolley, the trolley slidably coupled along rails of the hoist system, the rails provided by the upper support frame.
Example 8 includes the apparatus of any one or more of examples 4-7, including a drying rack coupled to the equipment rack adjacent the immersion tank.
Example 9 includes the apparatus of any one or more of examples 1-8, wherein the first CDU operates independently from the second CDU.
Example 10 includes the apparatus of any one or more of examples 1-9, wherein the controller is to adjust at least one of a first control valve or a first heater of the first CDU to provide the first immersion fluid at the first temperature, adjust at least one of a bypass valve or a first pump of the first CDU to modify a first flowrate of the first immersion fluid flowing from the first CDU to the first inlet of the immersion tank, adjust at least one of a second control valve or a second heater of the second CDU to provide the second immersion fluid at the second temperature, and adjust at least one of a second bypass valve or a second pump of the second CDU to modify a second flowrate of the second immersion fluid flowing from the second CDU to the second inlet of the immersion tank.
Example 11 includes an apparatus comprising memory, machine readable instructions, and at least one programmable circuit to execute the machine readable instructions to obtain a global immersion fluid temperature setpoint, operate a first coolant distribution unit (first CDU) to deliver first immersion fluid having a first temperature to a first inlet of an immersion tank based on the global immersion fluid temperature setpoint, obtain a target manifold immersion fluid temperature setpoint, and operate a second coolant distribution unit (second CDU) to deliver second immersion fluid having a second temperature to a second inlet of the immersion tank based on a target manifold immersion fluid temperature setpoint, the first inlet being different than the second inlet, and the first temperature being different than the second temperature.
Example 12 includes the apparatus of example 11, wherein one or more of the at least one programmable circuit is to obtain a first measured temperature of the first immersion fluid, compare the first measured temperature and the global immersion fluid temperature setpoint and in response to detecting that the first immersion fluid is less than the global immersion fluid temperature setpoint, control activation of a first heater, the first heater to heat processed chilled water to flow through a first heat exchanger within the first CDU to increase a temperature of the first immersion fluid.
Example 13 includes the apparatus of any one or more of examples 11-12, wherein one or more of the at least one programmable circuit is to obtain a second measured temperature of the second immersion fluid, compare the second measured temperature and the target manifold immersion fluid temperature setpoint and in response to detecting that the second immersion fluid is less than the target manifold immersion fluid temperature setpoint, control activation of a second heater, the second heater to heat processed chilled water to flow through a second heat exchanger within the second CDU to increase a temperature of the second immersion fluid.
Example 14 includes the apparatus of any one or more of examples 11-13, wherein one or more of the at least one programmable circuit is to obtain a first measured flowrate of the first immersion fluid exiting the first CDU, compare the first measured flowrate and a first immersion fluid flowrate setpoint, and adjust a first IF pump and/or a first IF bypass valve in the first CDU in response to detecting that first measured flowrate is outside of a first flowrate threshold range.
Example 15 includes the apparatus of any one or more of examples 11-14, wherein one or more of the at least one programmable circuit is to obtain a second measured flowrate of the second immersion fluid exiting the second CDU, compare the second measured flowrate and a second immersion fluid flowrate setpoint, and adjust one or more of a second IF pump or a second IF bypass valve in the second CDU in response to detecting that second measured flowrate is outside of a second flowrate threshold range.
Example 16 includes a non-transitory machine readable storage medium comprising instructions to cause at least one programmable circuit to at least obtain a global immersion fluid temperature setpoint, operate a first coolant distribution unit (first CDU) to deliver a first immersion fluid having a first temperature to a first inlet of an immersion tank based on the global immersion fluid temperature setpoint, obtain a target manifold immersion fluid temperature setpoint, and operate a second coolant distribution unit (second CDU) to deliver a second immersion fluid having a second temperature to a second inlet of the immersion tank based on a target manifold immersion fluid temperature setpoint, the first inlet being different than the second inlet, and the first temperature being different than the second temperature.
Example 17 includes the machine readable storage medium of example 16, wherein the instructions are to cause one or more of the at least one programmable circuit to obtain a second measured temperature of the second immersion fluid, compare the second measured temperature and the target manifold immersion fluid temperature setpoint and in response to detecting that the second immersion fluid is less than the target manifold immersion fluid temperature setpoint, control activation of a second heater, the second heater to heat processed chilled water to flow through a second heat exchanger within the second CDU to increase a temperature of the second immersion fluid.
Example 18 includes the apparatus of any one or more of examples 16-17, wherein the instructions are to cause one or more of the at least one programmable circuit to obtain a second measured temperature of the second immersion fluid, compare the second measured temperature and the target manifold immersion fluid temperature setpoint and in response to detecting that the second immersion fluid is less than the target manifold immersion fluid temperature setpoint, control activation of a second heater, the second heater to heat processed chilled water to flow through a second heat exchanger within the second CDU to increase a temperature of the second immersion fluid.
Example 19 includes the apparatus of any one or more of examples 16-18, wherein the instructions are to cause one or more of the at least one programmable circuit to obtain a first measured flowrate of the first immersion fluid exiting the first CDU, compare the first measured flowrate and a first immersion fluid flowrate setpoint, and adjust a first IF pump and/or a first IF bypass valve in the first CDU in response to detecting that first measured flowrate is outside of a first flowrate threshold range.
Example 20 includes the apparatus of any one or more of examples 16-19, wherein the instructions are to cause one or more of the at least one programmable circuit to obtain a global immersion fluid temperature setpoint, operate a first coolant distribution unit (first CDU) to deliver first immersion fluid having a first temperature to a first inlet of an immersion tank based on the global immersion fluid temperature setpoint, obtain a target manifold immersion fluid temperature setpoint, and operate a second coolant distribution unit (second CDU) to deliver second immersion fluid having a second temperature to a second inlet of the immersion tank based on a target manifold immersion fluid temperature setpoint, the first inlet being different than the second inlet, and the first temperature being different than the second temperature.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
an immersion tank having a first inlet and a second inlet different than the first inlet;
a first coolant distribution unit (CDU) fluidly coupled to the first inlet of the immersion tank;
a second coolant distribution unit (CDU) fluidly coupled to the second inlet of the immersion tank;
a controller to:
cause the first CDU to provide immersion fluid to the first inlet of the immersion tank at a first temperature that is within a first temperature threshold of a global temperature setpoint provided to the controller; and
cause the second CDU to provide immersion fluid to the second inlet of the immersion tank at a second temperature that is within a second temperature threshold of a target manifold setpoint provided to the controller; and
an equipment rack, wherein the immersion tank, the first CDU, the second CDU and the controller are coupled to the equipment rack.

2. The apparatus of claim 1, wherein the first CDU provides the first immersion fluid to a global distribution grate of the immersion tank, and the second CDU provides the second immersion fluid to a target manifold coupled to the immersion tank, the target manifold in fluid communication with one or more components of a server blade immersed in the immersion tank.

3. The apparatus of claim 1, wherein the first temperature is different from the second temperature.

4. The apparatus of claim 1, further including one or more infrastructure components and a hoist system, the one or more infrastructure components and the hoist system coupled to the equipment rack.

5. The apparatus of claim 4, wherein the equipment rack includes an upper support frame, a base support frame, and a side support frame extending between the upper support frame and the base support frame.

6. The apparatus of claim 5, wherein the upper support frame includes the hoist system to removably couple an electronic component from a cavity of the immersion tank.

7. The apparatus of claim 6, wherein the hoist system includes a hoist and a trolley, the trolley slidably coupled along rails of the hoist system, the rails provided by the upper support frame.

8. The apparatus of claim 4, including a drying rack coupled to the equipment rack adjacent the immersion tank.

9. The apparatus of claim 1, wherein the first CDU operates independently from the second CDU.

10. The apparatus of claim 1, wherein the controller is to:
adjust at least one of a first control valve or a first heater of the first CDU to provide the first immersion fluid at the first temperature;
adjust at least one of a bypass valve or a first pump of the first CDU to modify a first flowrate of the first immersion fluid flowing from the first CDU to the first inlet of the immersion tank;
adjust at least one of a second control valve or a second heater of the second CDU to provide the second immersion fluid at the second temperature; and
adjust at least one of a second bypass valve or a second pump of the second CDU to modify a second flowrate of the second immersion fluid flowing from the second CDU to the second inlet of the immersion tank.

11. An apparatus comprising:
memory;
machine readable instructions; and
at least one programmable circuit to execute the machine readable instructions to:
obtain a global immersion fluid temperature setpoint;
operate a first coolant distribution unit (first CDU) to deliver first immersion fluid having a first temperature to a first inlet of an immersion tank based on the global immersion fluid temperature setpoint;
obtain a target manifold immersion fluid temperature setpoint; and
operate a second coolant distribution unit (second CDU) to deliver second immersion fluid having a second temperature to a second inlet of the immersion tank based on a target manifold immersion fluid temperature setpoint, the first inlet being different than the second inlet, and the first temperature being different than the second temperature.

12. The apparatus of claim 11, wherein one or more of the at least one programmable circuit is to:
obtain a first measured temperature of the first immersion fluid;
compare the first measured temperature and the global immersion fluid temperature setpoint and
in response to detecting that the first immersion fluid is less than the global immersion fluid temperature setpoint, control activation of a first heater, the first heater to heat processed chilled water to flow through a first heat exchanger within the first CDU to increase a temperature of the first immersion fluid.

13. The apparatus of claim 11, wherein one or more of the at least one programmable circuit is to:
obtain a second measured temperature of the second immersion fluid;
compare the second measured temperature and the target manifold immersion fluid temperature setpoint and
in response to detecting that the second immersion fluid is less than the target manifold immersion fluid temperature setpoint, control activation of a second heater, the second heater to heat processed chilled water to flow through a second heat exchanger within the second CDU to increase a temperature of the second immersion fluid.

14. The apparatus of claim 11, wherein one or more of the at least one programmable circuit is to:
obtain a first measured flowrate of the first immersion fluid exiting the first CDU;
compare the first measured flowrate and a first immersion fluid flowrate setpoint; and
adjust a first IF pump and/or a first IF bypass valve in the first CDU in response to detecting that first measured flowrate is outside of a first flowrate threshold range.

15. The apparatus of claim 11, wherein one or more of the at least one programmable circuit is to:
obtain a second measured flowrate of the second immersion fluid exiting the second CDU;
compare the second measured flowrate and a second immersion fluid flowrate setpoint; and
adjust one or more of a second IF pump or a second IF bypass valve in the second CDU in response to detecting that second measured flowrate is outside of a second flowrate threshold range.

16. A non-transitory machine readable storage medium comprising instructions to cause at least one programmable circuit to at least:
obtain a global immersion fluid temperature setpoint;
operate a first coolant distribution unit (first CDU) to deliver a first immersion fluid having a first temperature to a first inlet of an immersion tank based on the global immersion fluid temperature setpoint;
obtain a target manifold immersion fluid temperature setpoint; and
operate a second coolant distribution unit (second CDU) to deliver a second immersion fluid having a second temperature to a second inlet of the immersion tank based on a target manifold immersion fluid temperature setpoint, the first inlet being different than the second inlet, and the first temperature being different than the second temperature.

17. The machine readable storage medium of claim 16, wherein the instructions are to cause one or more of the at least one programmable circuit to:
obtain a second measured temperature of the second immersion fluid;
compare the second measured temperature and the target manifold immersion fluid temperature setpoint and
in response to detecting that the second immersion fluid is less than the target manifold immersion fluid temperature setpoint, control activation of a second heater, the second heater to heat processed chilled water to flow through a second heat exchanger within the second CDU to increase a temperature of the second immersion fluid.

18. The machine readable storage medium of claim 16, wherein the instructions are to cause one or more of the at least one programmable circuit to:
obtain a second measured temperature of the second immersion fluid;
compare the second measured temperature and the target manifold immersion fluid temperature setpoint and
in response to detecting that the second immersion fluid is less than the target manifold immersion fluid temperature setpoint, control activation of a second heater, the second heater to heat processed chilled water to flow through a second heat exchanger within the second CDU to increase a temperature of the second immersion fluid.

19. The machine readable storage medium of claim 16, wherein the instructions are to cause one or more of the at least one programmable circuit to
obtain a first measured flowrate of the first immersion fluid exiting the first CDU;
compare the first measured flowrate and a first immersion fluid flowrate setpoint; and
adjust a first IF pump and/or a first IF bypass valve in the first CDU in response to detecting that first measured flowrate is outside of a first flowrate threshold range.

20. The machine readable storage medium of claim 16, wherein the instructions are to cause one or more of the at least one programmable circuit to:
obtain a global immersion fluid temperature setpoint;
operate a first coolant distribution unit (first CDU) to deliver first immersion fluid having a first temperature to a first inlet of an immersion tank based on the global immersion fluid temperature setpoint;
obtain a target manifold immersion fluid temperature setpoint; and
operate a second coolant distribution unit (second CDU) to deliver second immersion fluid having a second temperature to a second inlet of the immersion tank based on a target manifold immersion fluid temperature setpoint, the first inlet being different than the second inlet, and the first temperature being different than the second temperature.
